(19) United States
(12) Patent Application Publication
(10) Pub. No.: US 2025/0329620 A1
(43) Pub. Date: Oct. 23, 2025

(54) SEMICONDUCTOR DEVICES AND METHODS OF MANUFACTURING SEMICONDUCTOR DEVICES

(71) Applicant: Amkor Technology Singapore Holding Pte. Ltd., Singapore (SG)

(72) Inventors: Dae Young Park, Jeollanam-do (KR); Gi Jeong Kim, Gyeonggi-do (KR); Hyeong Il Jeon, Gyeonggi-do (KR); Ji Yeon Yang, Gyeonggi-do (KR); Kwang Soo Sang, Incheon (KR)

(73) Assignee: Amkor Technology Singapore Holding Pte. Ltd., Singapore (SG)

(21) Appl. No.: 18/638,600

(22) Filed: Apr. 17, 2024

(51) Int. Cl. H01L 23/495; H01L 21/48; H01L 21/56; H01L 23/00; H01L 23/552; H01L 25/065

(52) U.S. Cl. CPC H01L 23/49548; H01L 21/4828; H01L 21/561; H01L 23/49513; H01L 23/49537; H01L 23/49558; H01L 23/49575; H01L 23/49582; H01L 23/552; H01L 25/0655; H01L 24/16; H01L 24/29; H01L 24/32; H01L 24/45; H01L 24/48; H01L 24/49; H01L 24/73; H01L 24/83; H01L 24/85; H01L 24/92; H01L 24/97; H01L 2224/16245; H01L 2224/2929; H01L 2224/29339; H01L 2224/32245; H01L 2224/45144; H01L 2224/45147; H01L 2224/4801; H01L 2224/48091; H01L 2224/48245; H01L 2224/49173; H01L 2224/73265; H01L 2224/83192; H01L 2224/83201; H01L 2224/83439; H01L 2224/83444; H01L 2224/83464; H01L 2224/83469; H01L 2224/85439; H01L 2224/85444; H01L 2224/85464; H01L 2224/85469; H01L 2224/92247; H01L 2224/97; H01L 2924/0665; H01L 2924/20751; H01L 2924/20752; H01L 2924/20753; H01L 2924/20754; H01L 2924/20755

(57) ABSTRACT

In one example, an electronic device includes leads comprising a conductive material. A lead from the leads includes a base portion and a protrusion extending from a lower side of the base portion. A die paddle can be disposed between the leads and can include the conductive material. A lower mold can be disposed on a first lateral side of the protrusion and around lateral sides of the die paddle. A lower surface finish can be applied to a lower side of the protrusion. An electronic component can be coupled to the die paddle and in electronic communication with the lead. Other examples and related methods are also disclosed herein.

### TECHNICAL FIELD

The present disclosure relates, in general, to electronic devices, and more particularly, to semiconductor devices and methods for manufacturing semiconductor devices.

### BACKGROUND

Prior semiconductor packages and methods for forming semiconductor packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIGS. 1A and 1B show cross-sectional views of an example electronic device.

FIG. 1C shows a top perspective view of an example electronic device.

FIG. 1D shows a cross-sectional view of an example electronic device.

FIGS. 2A to 2L show cross-sectional views of an example method for manufacturing an example electronic device.

FIGS. 3A and 3B show cross-sectional views of an example electronic device.

FIG. 3C shows a cross-sectional view of an example electronic device.

FIGS. 4A to 4H show cross-sectional views of an example method for manufacturing an example electronic device.

FIG. 5A shows a cross-sectional view of an example electronic device.

FIG. 5B shows a cross-sectional view of an example electronic device.

FIG. 6A shows a top perspective view of an example electronic device.

FIGS. 6B and 6C show cross-sectional views of an example electronic device taken, respectively, along line A-A′ and line B-B′ in FIG. 6A.

FIGS. 7A to 7F show cross-sectional views of an example method for manufacturing an example electronic device.

FIG. 8 shows a cross-sectional view of an example electronic device.

FIG. 9A shows a top perspective view of an example electronic device.

FIGS. 9B, 9C, and 9D show cross-sectional views of an example electronic device taken, respectively, along line A-A′, line B-B′, and line C-C′ in FIG. 9A.

FIGS. 10A to 101 show cross-sectional views of an example method for manufacturing an example electronic device.

FIG. 11A shows a top perspective view of an example electronic device.

FIGS. 11B and 11C show cross-sectional views of an example electronic device taken, respectively, along line A-A′ and line B-B′ in FIG. 11A.

FIG. 12A shows a top perspective view of an example electronic device.

FIG. 12B shows cross-sectional view of an example electronic device taken along line A-A′ in FIG. 12A.

The following discussion provides various examples of semiconductor devices and methods of manufacturing semiconductor devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques may be omitted to avoid unnecessarily obscuring the present disclosure. In addition, elements in the drawing figures are not necessarily drawn to scale. For example, the dimensions of some of the elements in the figures may be exaggerated relative to other elements to help improve understanding of the examples discussed in the present disclosure. The same reference numerals in different figures denote the same elements.

The term “or” means any one or more of the items in the list joined by “or”. As an example, “x or y” means any element of the three-element set {(x), (y), (x, y)}. As another example, “x, y, or z” means any element of the seven-element set {(x), (y), (z), (x, y), (x, z), (y, z), (x, y, z)}.

The terms “comprises,” “comprising,” “includes,” and “including” are “open ended” terms and specify the presence of stated features, but do not preclude the presence or addition of one or more other features.

The terms “first,” “second,” etc. may be used herein to describe various elements. The elements described using “first,” “second,” etc. should not be limited by these terms. The terms “first,” “second,” etc. are only used to distinguish one element from another. Thus, for example, a first element discussed in this disclosure could be termed a second element without departing from the teachings of the present disclosure.

Unless specified otherwise, the term “coupled” may be used to describe two elements directly contacting each other or to describe two elements indirectly coupled by one or more other elements. For example, if element A is coupled to element B, then element A can be directly contacting element B or indirectly coupled to element B by an intervening element C. Similarly, the terms “over” or “on” may be used to describe two elements directly contacting each other or describe two elements indirectly coupled by one or more other elements. As used herein, the term coupled can refer to an electrical coupling or a mechanical coupling.

### DESCRIPTION

An example electronic device can include leads comprising a conductive material. A lead from the leads includes a base portion and a protrusion extending from a lower side of the base portion. A die paddle can be disposed between the leads and can include the conductive material. A lower mold can be disposed on a first lateral side of the protrusion and around lateral sides of the die paddle. A lower surface finish can be applied to a lower side of the protrusion. An electronic component can be coupled to the die paddle and in electronic communication with the lead.

An example method of manufacturing an electronic device may include the step of providing leads comprising a conductive material. A lead from the leads can include a base portion and a protrusion extending from a lower side of the base portion. A die paddle comprising the conductive material is provided and can be disposed between the leads. The method can further include the steps of providing a lower mold on a first lateral side of the protrusion and around lateral sides of the die paddle, applying a lower surface finish to a lower side of the protrusion, and providing an electronic component coupled to the die paddle and in electronic communication with the lead.

Another example electronic device can include a lead comprising a conductive material. The lead may include a base portion and a protrusion extending from a lower side of the base portion. A die paddle may be disposed adjacent the lead and may comprise the conductive material. A lower mold may be disposed on a first lateral side of the protrusion and around lateral sides of the die paddle. The lower mold can be between the lead and the die paddle. A surface finish can be applied to a lower side of the protrusion to form a wettable flank. An electronic component can be coupled to the die paddle and in electronic communication with the lead.

Other examples are included in the present disclosure. Such examples may be found in the figures, in the claims, or in the description of the present disclosure.

Electronic devices of the present disclosure can comprise routable micro lead frames (rtMLF) made using multi-stage molding and patterning processes. The resulting electronic devices can include wettable surfaces or wettable flanks that tend to improve soldering performance. The term “wettable flank” as used herein can describe a conductive structure having an L-shape or stepped shape to bound a flowable material laterally. Leads can be patterned from a metal material and molded together using multiple applications of moldable material with a surface treatment applied on the moldable materials. Electronic devices of the present disclosure tend to have higher reliability with reduced metal burring. Electronic devices of the present disclosure can also include wettable flanks while reducing lateral exposure of copper or other interconnect material. Electromagnetic interference (EMI) shielding can be integrated using conductive paste, vertical wire, wire fence, wire cage, or other EMI shielding techniques.

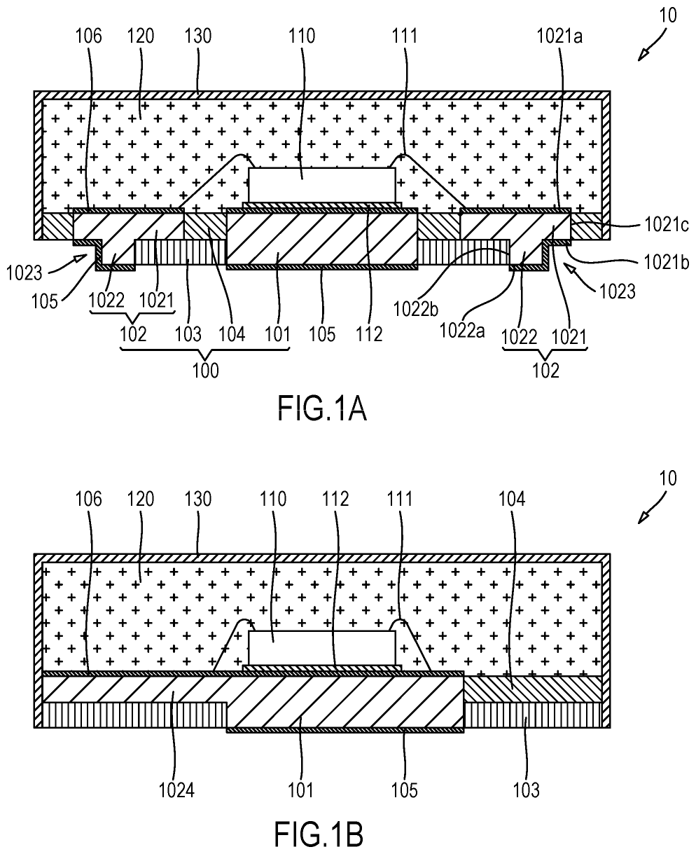

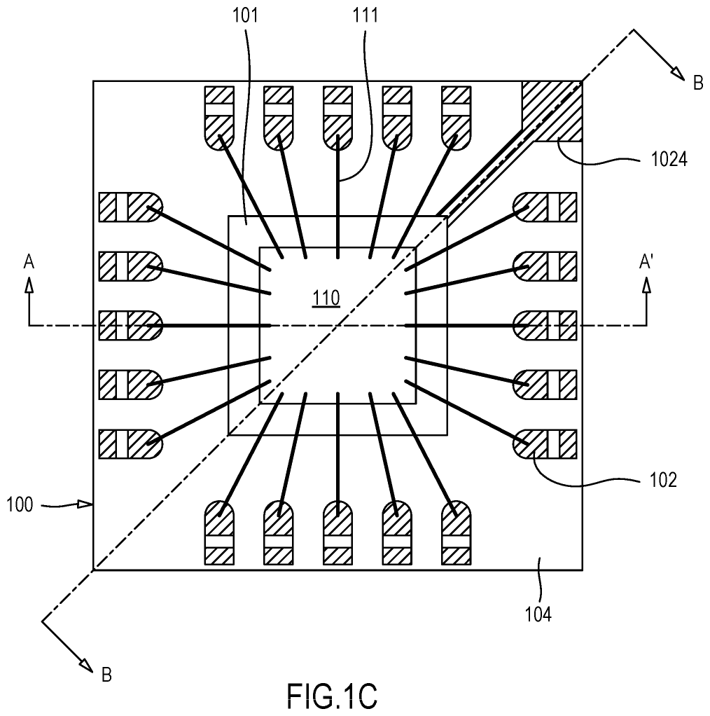

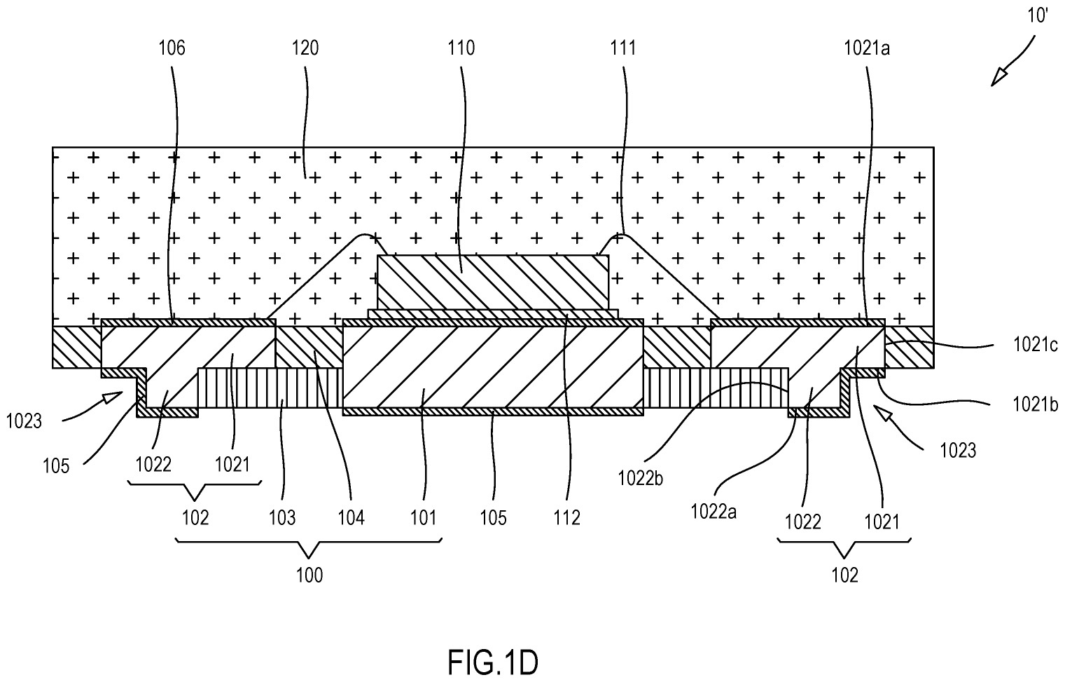

FIGS. 1A and 1B show cross-sectional views of an example electronic device 10, and FIG. 1C shows a top perspective view of example electronic device 10. FIG. 1A is taken along line A-A′ of FIG. 1C, and FIG. 1B is taken along line B-B′ of FIG. 1C. In the example shown in FIGS. 1A, 1B, and 1C, electronic device 10 can comprise substrate 100, electronic component 110, encapsulant 120, and shield 130.

Substrate 100 can comprise die paddle 101, leads 102, lower mold 103, and upper mold 104. Leads 102 can comprise base portion 1021, protrusion 1022, and wettable flank 1023. Base portion 1021 and protrusion 1022 can form or define wettable flank 1023 of lead 102. Substrate 100 can also include one or more ground lead(s) 1024. In some examples, ground lead 1024 can extend diagonally from a corner of die paddle 101. Ground lead 1024 can be formed integrally with die paddle 101 and disposed over lower mold 103. Base portion 1021 of each lead 102 can comprise base upper side 1021a, base lower side 1021b, and base lateral sides 1021c. Protrusion 1022 can comprise protrusion lower side 1022a and protrusion lateral sides 1022b. In FIG. 1C, the “cross-hatching” shown on leads 102 and ground lead 1024 identifies area of the leads having a reduced thickness or half thickness, as compared to the thickness of other areas of leads 102 or die paddle 101.

In some examples, lower surface finish 105 can be located along the bottom sides of die paddle 101 and leads 102 (e.g., along wettable flank 1023 and protrusion lower side 1022a). Upper surface finish 106 can be located along the top sides of die paddle 101 and leads 102 (e.g., along base upper side 1021a and ground lead 1024). Electronic component 110 can comprise component interconnects 111. Component interconnects 111 can electrically couple electronic component to substrate 100. Attachment material 112 can couple electronic component 110 to die paddle 101.

Substrate 100, encapsulant 120, and shield 130 can be referred to as a semiconductor package. The package can protect electronic component 110 from external elements and/or external exposure. The package can also provide electrical coupling between external electronic components and electronic component 110.

FIG. 1D shows a cross-sectional view of an example electronic device 10′. In the example shown in FIG. 1D, electronic device 10′ is similar to electronic device 10 shown in FIG. 1A with shield 130 omitted. In electronic device 10′, the lateral sides of upper mold 104 and the top and lateral sides of encapsulant 120 are exposed.

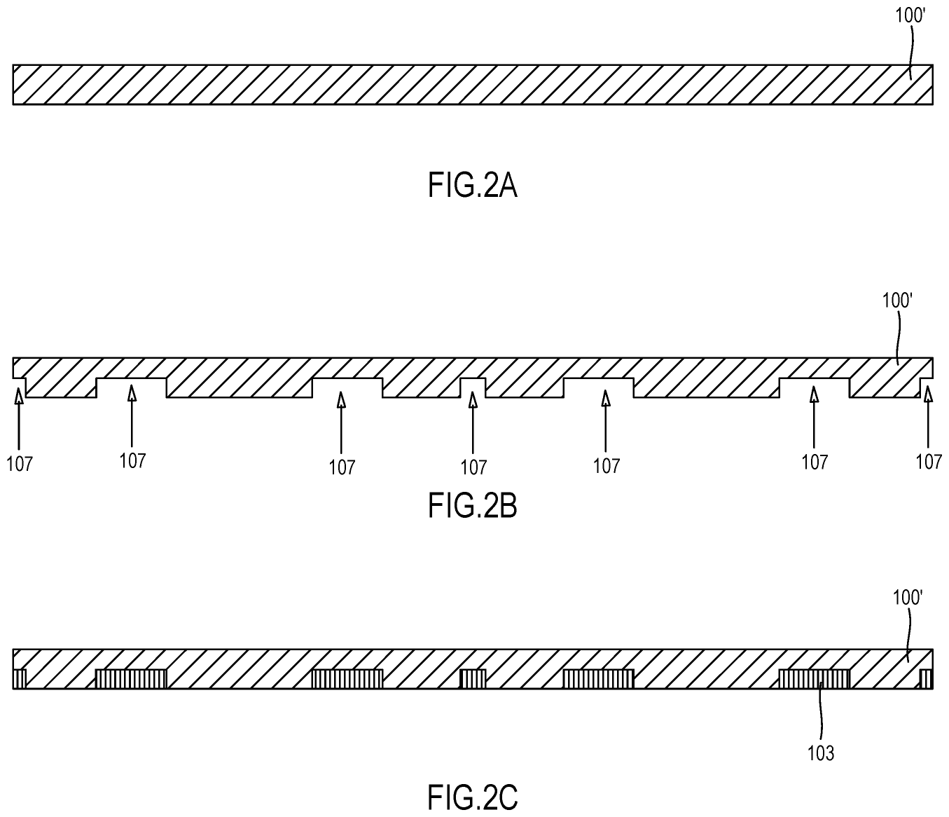

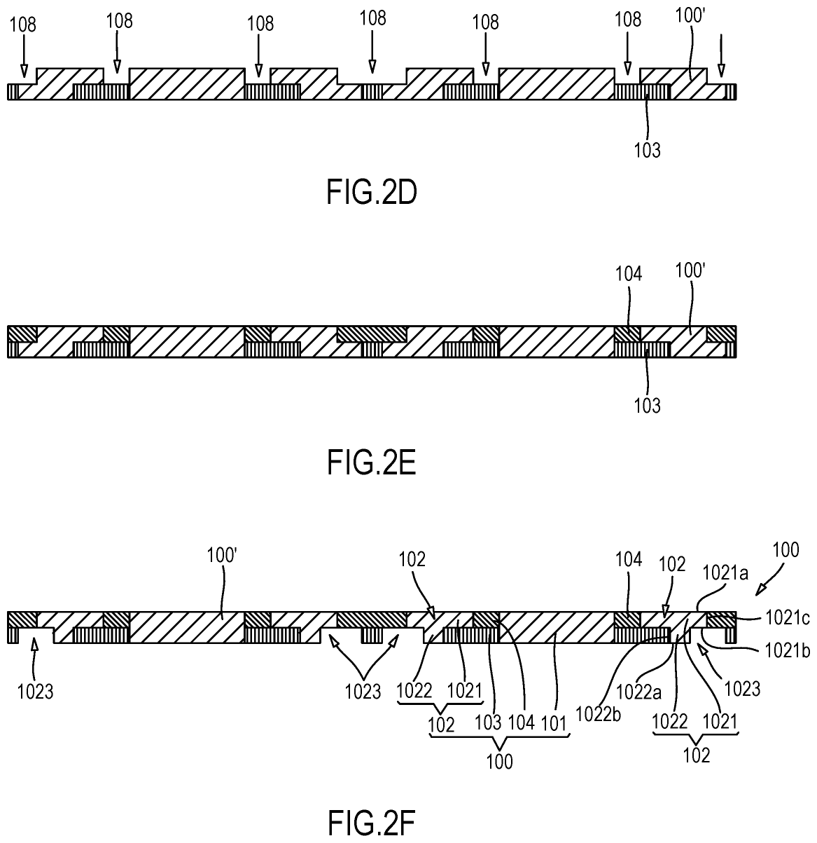

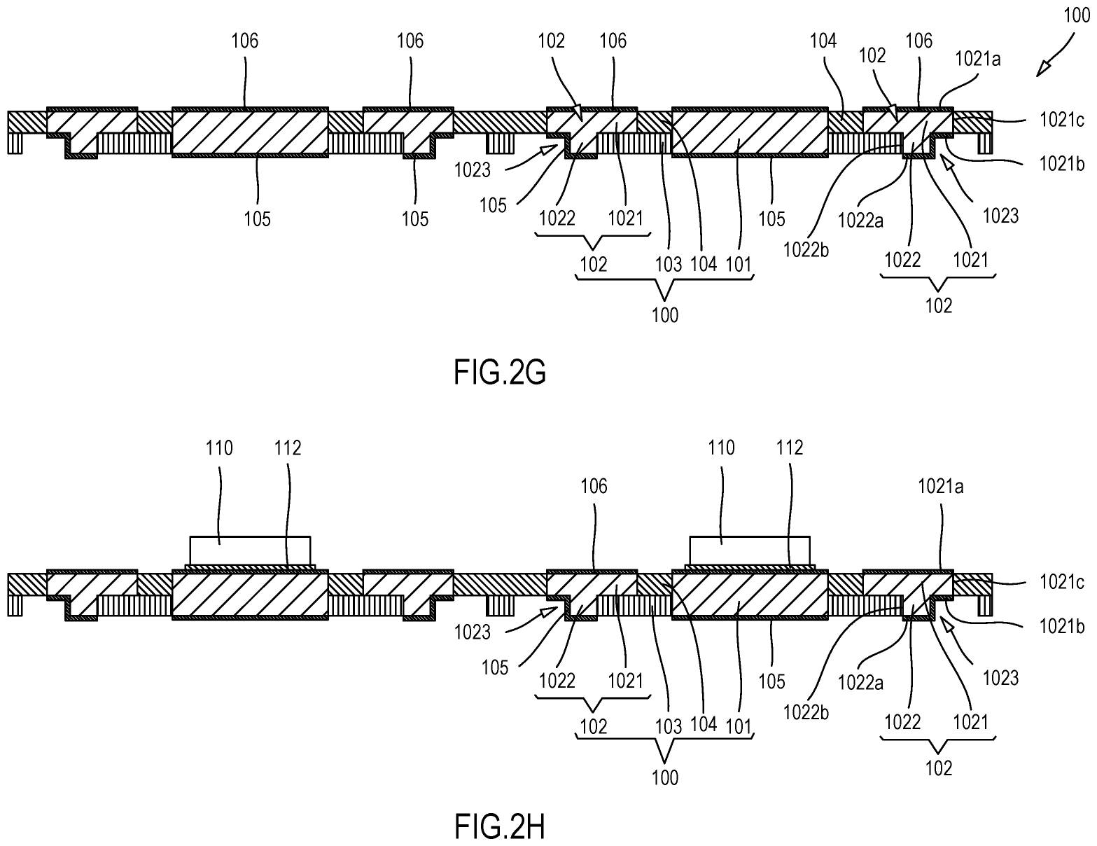

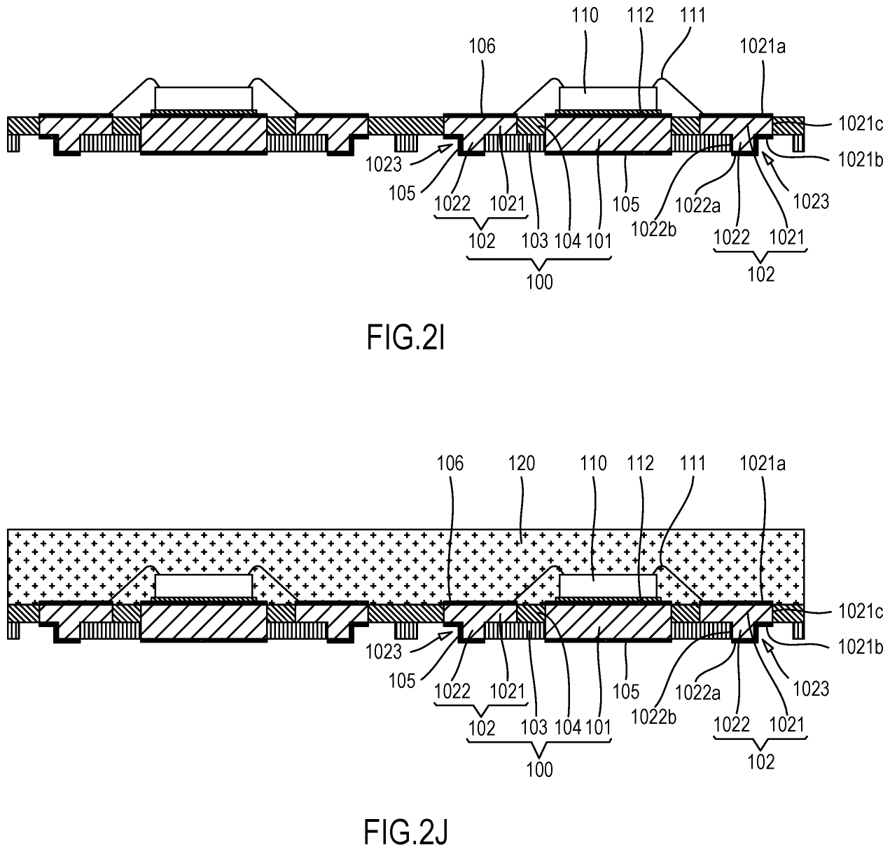

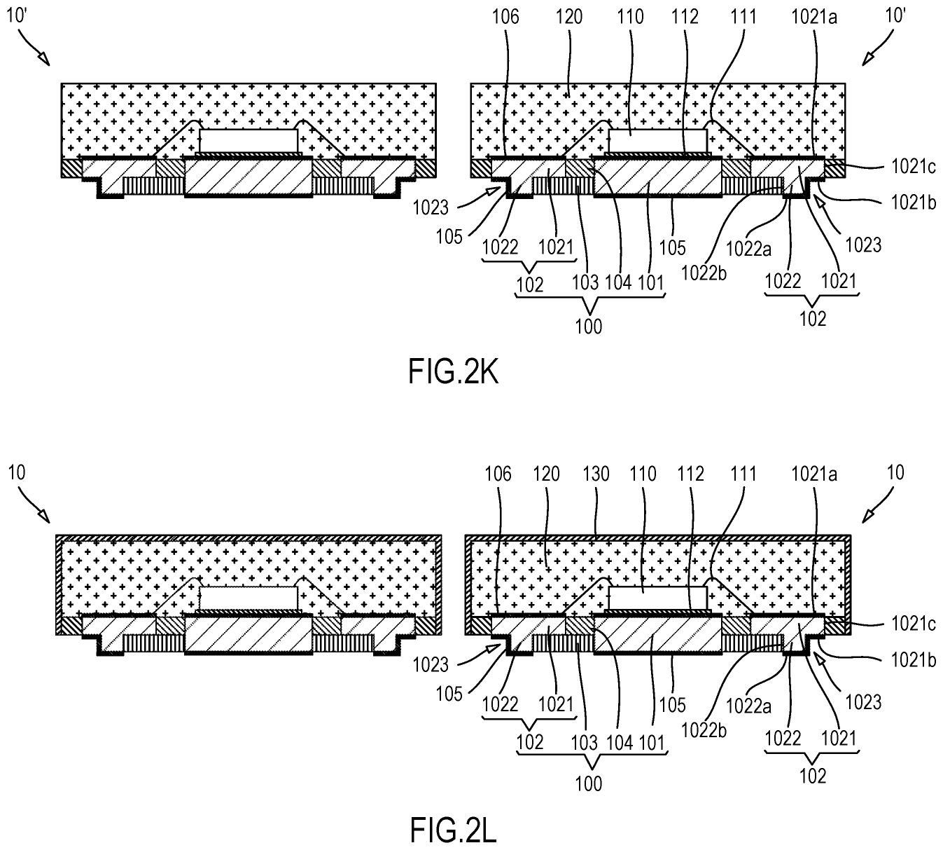

FIGS. 2A to 2L show cross-sectional views of an example method for manufacturing an example electronic device 10 or 10′. In some examples, the method illustrated by FIGS. 2A to 2L can be referred to as a “wettable flank first” or “die last” process.

FIG. 2A shows a cross-sectional view of electronic device 10 or 10′ at an early stage of manufacture. In the example shown in FIG. 2A, raw material 100′ for substrate 100 can be provided. Raw material 100′ can comprise a generally planar top side and a generally planar bottom side opposite to the top side. Raw material 100′ can comprise or be referred to as a conductor or a conductive thin plate. In some examples, raw material 100′ can comprise a conductive material having a coefficient of thermal expansion similar to silicon and having excellent thermal or electrical conductivity. In some examples, raw material 100′ can comprise Cu, Cu—Fe—P, Cu—Ni—Si, or Ni—Fe (e.g., Alloy 42 comprising approximately 42% Ni and the balance Fe). Raw material 100′ can generally be provided as thick rolled or cold rolled metal. The thickness of raw material 100′ can range from approximately 125 μm (micrometers) to approximately 250 μm. Raw material 100′ can provide die paddle 101, leads 102, and ground lead 1024 of substrate 100, as described below.

FIG. 2B shows a cross-sectional view of electronic device 10 or 10′ at a later stage of manufacture. In the example shown in FIG. 2B, recesses or grooves 107 are provided in the lower (or first) side of raw material 100′. In some examples, recesses 107 can be formed by etching raw material 100′. For example, a photoresist can be applied or laminated to the lower side of raw material 100′ and then a portion of the lower side of raw material 100′ (e.g., the portion of raw material 100′ to be etched and removed) can be treated through an exposure and development process. By providing an etchant to the exposed lower side of raw material 100′, regions of the lower side of raw material 100′ can be removed, thereby forming recesses 107 in the lower side of raw material 100′. In some examples, the depth of recess 107 can be approximately 50% to approximately 70% of the total thickness of raw material 100′. As used herein with reference to linear distances, the term approximately can mean +/−5%, +/−10%, +/−15%, +/−20%, or +/−25%. After the etching process on the lower side is completed, the remaining photoresist can be removed.

FIG. 2C shows a cross-sectional view of electronic device 10 or 10′ at a later stage of manufacture. In the example shown in FIG. 20, lower mold 103 is provided in recesses 107 (FIG. 2B). Lower mold 103 can fill recesses 107 in raw material 100′. In some examples, lower mold 103 can physically or chemically protect raw material 100′ (e.g., die paddle 101, leads 102, and ground lead 1024) and/or provide electrical isolation between die paddle 101, leads 102, and ground lead 1024, as described below. Lower mold 103 can comprise a material having excellent adhesion to raw material 100′. Lower mold 103 can include a material that has good heat radiation characteristics to expel heat from raw material 100′. Lower mold 103 can have excellent formability into a desired shape. In some examples, lower mold 103 can comprise or be referred to as a resin, polymer with filler, epoxy mold compound, encapsulant, or a protective material. In some examples, lower mold 103 can be provided by a transfer molding method using mold material provided in tablet form, a compression molding method using mold material (e.g., resin) provided in powder (powder/granule) form, a liquid molding method using mold material provided in liquid form, or vacuum lamination method using mold material provided in film form. In some examples, after providing lower mold 103, a grinding process can be performed to planarize of the lower sides of lower mold 103 and raw material 101′. In response to the grinding process, the lower side of raw material 100′ and the lower side of lower mold 103 can be coplanar (e.g., substantially on the same plane).

FIG. 2D shows a cross-sectional view of electronic device 10 or 10′ at a later stage of manufacture. In the example shown in FIG. 2D, recesses or grooves 108 are provided in the upper (or second) side of raw material 100′. In some examples, recesses 108 can be formed by etching raw material 100′. For example, a photoresist can be applied or laminated to the upper side of raw material 100′ and then a portion of the upper side of raw material 100′ (e.g., the portion of raw material 100′ to be etched and removed) can be treated through an exposure and development process. By selectively providing an etchant to the exposed upper side of raw material 100′, regions of the upper side of raw material 100′ can be removed, thereby forming recesses 108 in the upper side of raw material 100′.

In accordance with various examples, recesses 108 can be located in areas corresponding to, vertically overlapping, or within the footprint of recesses 107 (FIG. 2B) and lower mold 103 in the lower side of raw material 100′. In some examples, recesses 108 can be provided in an area that does not vertically overlap or is outside the footprint of recesses 107 and lower mold 103. In some examples, the depth of recesses 108 can be approximately 30% to approximately 50% of the total thickness of raw material 100′. In regions where recesses 108 vertically overlap recesses 107 and lower mold 103, the combination of recess 107 and recess 108 can extend completely through raw material 100′. Some regions of lower mold 103 can be exposed through the upper side of raw material 101′ by recesses 108. After the etching process on the upper side is completed, the remaining photoresist can be removed.

FIG. 2E shows a cross-sectional view of electronic device 10 or 10′ at a later stage of manufacture. In the example shown in FIG. 2E, upper mold 104 is provided in recesses 108 (FIG. 2D). Upper mold 104 can fill recesses 108 on the upper side of raw material 100′. In some examples, upper mold 104 can be coupled to or in contact with lower mold 103. In some examples, the materials and methods of providing upper mold 104 can be similar to, or the same as, those of providing lower mold 103 described above. In some examples, after providing upper mold 104, a grinding process can planarize the upper sides of upper mold 104 and raw material 100′. In response to the grinding process, the upper side of raw material 100′ and the upper side of upper mold 104 can be coplanar.

FIG. 2F shows a cross-sectional view of electronic device 10 or 10′ at a later stage of manufacture. In the example shown in FIG. 2F, wettable flanks 1023 are provided in the lower side of raw material 100′. In some examples, wettable flanks 1023 can be provided using an etching process (e.g., portions of raw material 100′ can be removed via etching). For example, a photoresist can be applied or laminated to the lower side of raw material 100′ and lower mold 103, and a portion of the lower side of raw material 100′ (i.e., the area to be etched away) can be exposed. By providing an etchant to the exposed lower side of raw material 100′, a portion of raw material 100′ can be removed to provide wettable flank 1023. In some examples, a portion of lower mold 103 can also be removed during the etching process used to form wettable flank 1023. After etching, the remaining photoresist can be removed. In some examples, the depth of the wettable flanks 1023 can be approximately 50% to approximately 70% of the total thickness of raw material 100′. In some examples, after forming wettable flank 1023, upper mold 104 can be exposed from the lower side of raw material 100′.

In accordance with various examples, substrate 100 comprising die paddle 101, leads 102, ground lead 1024 (FIGS. 1B and 1C), lower mold 103, and upper mold can be provided by the above-described processes. Die paddle 101, leads 102, and ground lead 1024 of substrate 100 can be provide from raw material 100′. In some examples, Substrate 100 can comprise or be referred to as a leadframe, a routable leadframe, a routable molded leadframe, a molded leadframe, or a molded substrate. In some examples, in order to improve production efficiency, substrate 100 can be prepared in a matrix form or strip form with multiple rows and columns of substrates 100. In some examples, substrate 100 can be prepared in the form of a disk or square panel, and a plurality of substrates 100 arrayed within the disk or square panel.

As described above, each of leads 102 can comprise base (or upper) portion 1021 and protrusion (or lower portion) 1022 extending downward from base portion 1021. Base portion 1021 can comprise substantially planar base upper side 1021a, substantially planar base lower side 1021b opposite base upper side 1021a, and base lateral sides 1021c extending between base upper side 1021a and base lower side 1021b. The thickness of base portion 1021, as measured between base upper side 1021a, and base lower side 1021b, can range from approximately 50 μm to approximately 100 μm. Protrusion 1022 can comprise substantially planar protrusion lower side 1022a and substantially planar protrusion lateral sides 1022b extending between protrusion lower side 1022a and base lower side 1021b. In some examples, the width of protrusion 1022, as measured along protrusion lower side 1022a, can be less than the width of base portion 1021, as measured along base upper side 1021a. For example, the thickness of protrusion 1022, as measured between protrusion lower side 1022a and base lower side 1021b, can range from approximately 25 μm to approximately 250 μm, from approximately 35 μm to approximately 125 μm, from approximately 75 μm to approximately 200 μm, from approximately 125 μm to approximately 150 μm, or other suitable lengths. Wettable flanks 1023 can comprise or be defined by base lower side 1021b and protrusion lateral sides 1022b and can be exposed through lower mold 103 and upper mold 104. Wettable flanks 1023 can provide excellent solder adhesion by expanding the surface area of leads 102 exposed from lower mold 103 or upper mold 104. Additionally, forming wettable flanks 1023 using an etching process rather than a mechanical process (e.g., stamping or cutting) can decrease or prevent generation of metal burrs at the edges of the raw material 101′. Preventing or decreasing occurrences of burrs tends to increase electrical performance and/or reliability, as occurrences of physical bridging (i.e., short circuiting) between leads, which can be caused by burrs and/or by environmentally induced Cu migration, is reduced or prevented.

FIG. 2G shows a cross-sectional view of electronic device 10 or 10′ at a later stage of manufacture. In the example shown in FIG. 2G, a surface finishing process can be performed. Lower surface finish 105 can be provided on the lower side of die paddle 101 and leads 102. Upper surface finish 106 can be provided on the upper sides of die paddle 101, leads 102, and ground lead 1024 (FIG. 2B). In some examples, upper surface finish 106 can be provided on base upper side 1021a. In some examples, lower surface finish 105 can be provided on protrusion lower side 1022a, and on the protrusion lateral side 1022b and base lower side 1021b that are exposed through lower mold 103 (e.g., on regions of wettable flanks 1023).

Lower surface finish 105 and upper surface finish 106 can comprise a plating layer or diffusion area. In some examples, the plating layer can comprise silver (Ag), gold (Au), platinum (Pt), or palladium (Pd). In some examples, a silver-plating layer of approximately 0.5 μm to approximately 2 μm can be provided on the surface of die paddle 101 and leads 102 exposed through lower mold 103 or upper mold 104 of substrate 100. In some examples, a mask can be provided on substrate 100 with regions of the die paddle 101 and leads 102 exposed from the mask, and a plating solution can be sprayed on the regions of die paddle 101 and leads 102 that are exposed from the mask or substrate 100 can be immersed in a silver-plating bath. In some examples, by heat treatment, the silver-plating layer can be diffused into die paddle 101 and leads 102 to provide silver diffusion areas. Heat treatment temperature and heat treatment time can be adjusted in various ways depending on the type of substrate 100. The surface finish can be a metal having good conductivity and resistance to oxidation, and can improve adhesion with gold wire, copper wire, or solder.

Lower surface finish 105 provided on wettable flanks 1023 and protrusion lower side 1022a can enclose or isolated leads 102 from ambient air. Regions of leads 102 without lower surface finish 105 or upper surface finish 106 can be located inside lower mold 103 or upper mold 104. For example, the base lateral sides 1021c without lower surface finish 105 or upper surface finish 106 can be in upper mold 104, and the protrusion lateral sides 1022b and base lower side(s) 1021b without lower surface finish 105 can be in lower mold 103. Enclosing or completely surrounding leads 102 with upper surface finish 106, lower surface finish 105, upper mold 104, and lower mold 103 can protect leads 102 from oxidation through exposure to ambient conditions. By providing lower surface finish 105 on the entire surface of wettable flanks 1023, wettable flanks 1023 can also be protected from oxidation. Upper surface finish 106 provided on leads 102 can enable component interconnects 111 (FIG. 2I) to be more easily connected to leads 102. Wettable flanks 1023 and/or lower surface finish 105 tend to improve solder adhesion when electronic device 10 or 10′ is mounted on an external device. Wettable flanks 1023 also tend to allow for and/or improve visual inspection when electronic device 10 or 10′ is mounted on an external device in a later process.

FIG. 2H shows a cross-sectional view of electronic device 10 or 10′ at a later stage of manufacture. In the example shown in FIG. 2H, electronic component 110 is provided over die paddle 101. Electronic component 110 can comprise or be referred to as a semiconductor die, semiconductor chip, semiconductor package, semiconductor device, active component, or passive component. Electronic component 110 can comprise or be referred to as a digital signal processor (DSPs), a network processor, a power management unit, an audio processor, a wireless baseband system-on-chip (SoC) processor, a sensor, a custom integrated circuit, a memory, an antenna on package (AoP), an antenna in package (AiP), a 5G NR millimeter wave (mmWave) module, a sub-6 gigahertz (GHz) radio frequency (RF) module, or an integrated passive device (IPD).

In some examples, electronic component 110 can be coupled to die paddle 101 via attach material 112. In some examples, attach material 112 can comprise or be referred to as an adhesive, adhesive film, or die attach film. In some examples, electronic component 110 can be coupled to die paddle 101 via an attach material 112 comprising silver epoxy paste or silver filled epoxy. In some examples, attach material 112 can first be attached to die paddle 101 and then electronic component 110 can be pressed against attach material 112 to couple electronic component 110 to die paddle 101. In some examples, attach material 112 can first be attached to electronic component 110 and then electronic component 110, with attach material 112 coupled thereto, can be mounted onto die paddle 101. In some examples, heat can be provided simultaneously with pressurization. The thickness of electronic component 110 can range from approximately 50 μm to approximately 800 μm. In some examples, electronic component 110 can perform various operations, such as processing, amplifying, filtering, or data storage, for example.

FIG. 2I shows a cross-sectional view of electronic device 10 or 10′ at a later stage of manufacture. In the example shown in FIG. 2I, component interconnects 111 are provided. In accordance with various examples, one end of component interconnect 111 can be coupled to electronic component 110 and the other end of component interconnect 111 can be coupled to lead 102. In some examples, one end of a component interconnect 111 can be bonded to electronic component 110 and the other end can be bonded to die paddle 101 (for example, a ground component interconnect 111). Electronic component 110 can be in electronic communication with lead 102 through component interconnect 111. Component interconnects 111 can comprise or be referred to as wires (e.g., gold wires or copper wires). The diameters of component interconnects 111 can range from approximately 10 μm to approximately 50 μm. Component interconnects 111 can transfer electrical signals between electronic component 110 and leads 102. Component interconnects 111 can transfer electrical signals (e.g., ground signals) between electronic component 110 and die paddle 101.

FIG. 2J shows a cross-sectional view of electronic device 10 or 10′ at a later stage of manufacture. In the example shown in FIG. 2J, encapsulant 120 is provided over electronic component 110 and substrate 100. Encapsulant 120 can cover electronic component 110, component interconnects 111 and/or substrate 100. Encapsulant 120 can contact substrate 100, electronic component 110, and component interconnects 111. In some examples, encapsulant 120 can contact die paddle 101, leads 102, ground lead 1024 (FIG. 1B), and upper mold 104 of substrate 100. In some examples, encapsulant 120 can contact upper surface finish 106 of die paddle 101, leads 102, and ground lead 1024. Encapsulant 120 can comprise or be referred to as an epoxy molding compound, resin, filler-reinforced polymer, a B-stage compressed film, or gel. In some examples, encapsulant 120 can comprise epoxy resin or phenol resin, carbon black, and silica filler. In some examples, encapsulant 120 can be provided by compression molding, transfer molding, liquid encapsulant molding, vacuum lamination, paste printing, or film assisted molding. Compression molding can be a process for supplying a fluid molding material (e.g., resin) into a mold in advance and then putting an electronic component into the mold and curing the fluid molding material. Transfer molding is a process for supplying mold material around an electronic component using a gate (supply port). The thickness of encapsulant 120 can range from approximately 100 μm to approximately 1000 μm. Encapsulant 120 can protect electronic component 110 and component interconnects 111 from exposure to external elements or environments, and can quickly dissipate heat from electronic component 110. The material of encapsulant 120 can be the same or different from the material of upper mold 104 and/or lower mold 103.

FIG. 2K shows a cross-sectional view of electronic device 10 or 10′ at a later stage of manufacture. In the example shown in FIG. 2K, a singulation process is performed to provide individual, discrete electronic devices 10 and 10′. For example, a singulation tool (e.g., a saw, blade, cutter, laser, etc.) can saw or otherwise cut through encapsulant 120 and substrate 100 to separate individual electronic devices 10 and 10′ from one another. In accordance with various examples, the singulation tool (e.g., a diamond blade wheel) saws through upper mold 104 and lower mold 103 of substrate 100. Ground lead 1024 (FIG. 1B) can also be sawed while other leads 102 remain unsawn. For example, a portion of top mold 104 is located between base portion 1021 and the lateral side (i.e., sawn edge) of top mold 104. In various examples, a portion of ground lead 1024 (e.g., the sawed lateral side(s)) can be exposed through encapsulant 120, upper mold 104, and lower mold 103, as shown in FIGS. 1B and 1C. Leads 102 can be unsawn, and thus leads 102 can remain completely or substantially covered along the lateral sides of substrate 100. Singulating through upper mold 104 and lower mold 103 without sawing through leads 102 can decrease or prevent the generation of metal burrs at the lateral sides of substrate 100. Preventing or decreasing occurrences of burrs and/or having leads 102 covered by top mold 104 tends to increase electrical performance and/or reliability, as occurrences of physical bridging (i.e., electrical shorting) between leads 102, which can be caused by metal burrs and/or by environmentally induced Cu migration, is reduced or prevented.

In response to singulation, the lateral sides of encapsulant 120 and substrate 100 can be coplanar. In some examples, the lateral sides of encapsulant 120, the lateral sides of upper mold 104, and the lateral sides of lower mold 103 can be coplanar. In response to singulation, the lateral sides of encapsulant 120, the lateral sides of upper mold 104, and the lateral sides of lower mold 103 are exposed at the outer sides of the device. In this way, electronic device 10′ can be provided.

FIG. 2L shows a cross-sectional view of electronic device 10 at a later stage of manufacture. In the example shown in FIG. 2L, shield 130 is provided. Shield 130 can cover the upper and lateral sides of encapsulant 120. In some examples, shield 130 can cover the lateral sides of substrate 100. In some examples, shield 130 can cover the lateral sides of upper mold 104. In some examples, the shield 130 can be electrically connected to exposed ground lead 1024 (FIG. 1B). The shield 130 can be spaced apart from the signal or power supply leads 102 and upper mold 104 can be between signal or power supply leads 102 and shield 130. Shield 130 can comprise or be referred to as an EMI shield or conformal shield. In some examples, shield 130 can be provided by a sputtering process, a plating process, a spray coating process, a plasma deposition process, or a taping process. In some examples, in the sputtering process, a conformal shield is deposited using a target material in a vacuum, which can provide improved density, contact resistance. Thin film adhesion of the shield can control the thickness and have a high yield.

In some examples, a sputtering process can be performed multiple times using the same metal or different metals. In some examples, a plating process can be performed and can be an electroless method of plating through a chemical reaction without using an external power source. In some examples, the plating process can allow reactions to proceed continuously through a spontaneous reduction reaction by simultaneously adding metal ions and a reducing agent to the plating solution. In some examples, an electrolytic plating process can be performed after the electroless plating process. In some examples, a spray coating process can be performed and can include a coating using a conductive mixed paint formed by mixing conductive powder or flakes with a resin such as silicone, epoxy, acrylic, or polyurethane. Since an ink-type shielding material containing conductive powder is applied by spraying, the spray coating process exhibits high productivity and can be applied to various types of devices. In some examples, spray coating can also be performed multiple times. In some examples, shield 130 can comprise copper (Cu), aluminum (Al), nickel (Ni), palladium (Pd), gold (Au), silver (Ag), chromium (Cr), zinc (Zn), tin (Sn), titanium (Ti), iron (Fe), carbon black, or alloys thereof. In some examples, shield 130 can also comprise resin such as silicone, epoxy, acrylic, or polyurethane along with conductive powder. In some examples, the thickness of shield 130 can range from approximately 3 μm to approximately 10 μm. Shield 130 can inhibit electronic component 110 from radiating electromagnetic waves. Shield 130 can also inhibit penetration of electromagnetic waves into electronic component 110.

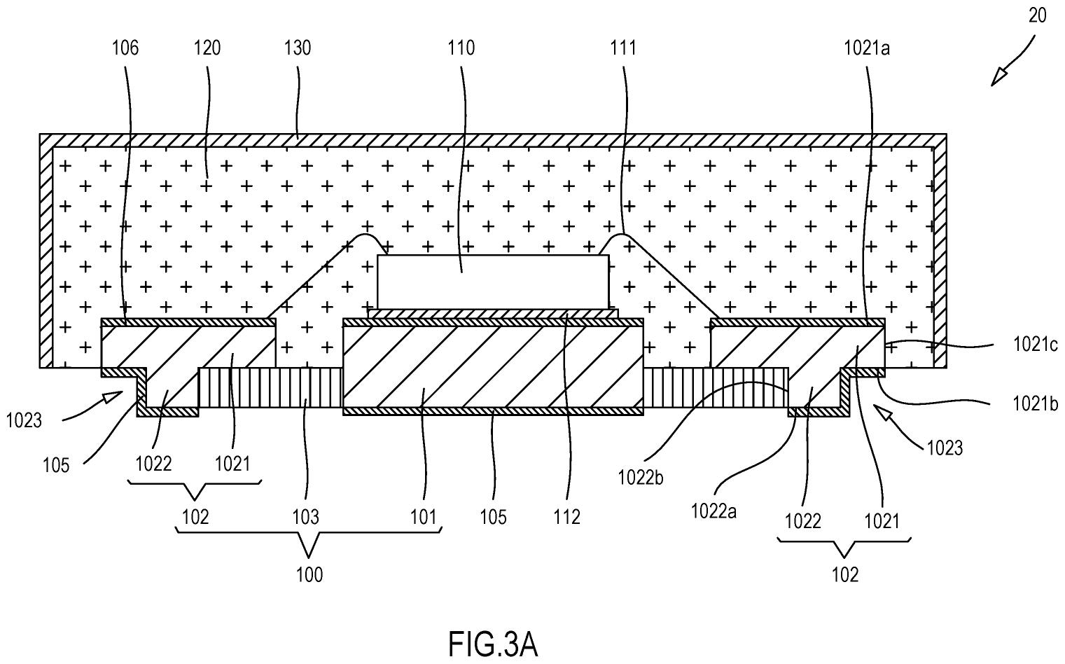

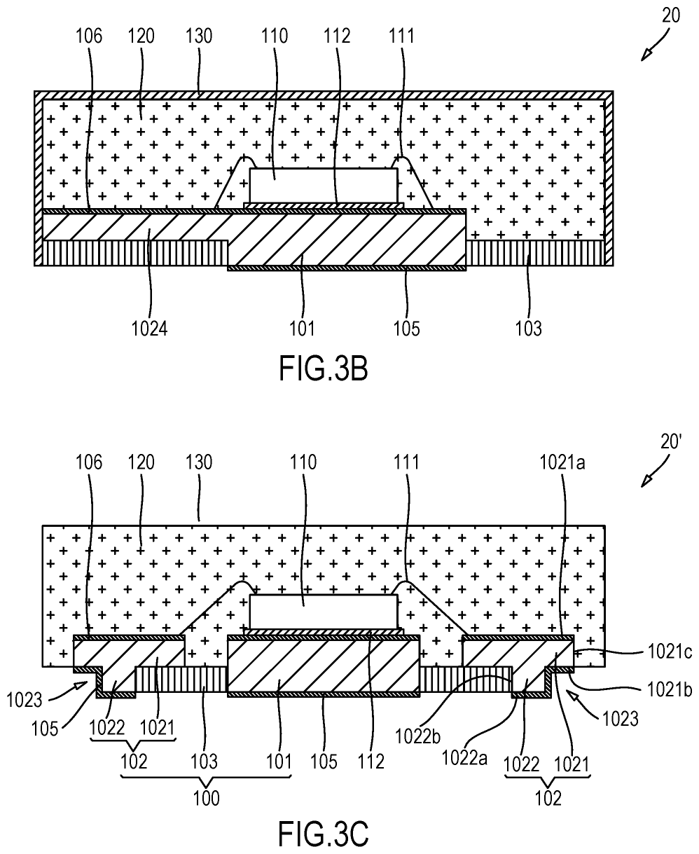

FIGS. 3A and 3B show a cross-sectional view of an example electronic device 20. Electronic device 20 shown in FIGS. 3A and 3B can be similar to electronic device 10, shown in FIGS. 1A and 1B, with upper mold 104 omitted. In electronic device 20, encapsulant 120 can contact the lateral sides of die paddle 101 and ground lead 1024. In electronic device 20, encapsulant 120 can contact base lateral sides 1021c of leads 102. In electronic device 20, encapsulant 120 can contact the upper side of lower mold 103. In some examples, the lower side of encapsulant 120 and base lower side 1021b of leads 102 can be coplanar (i.e., be located along the same plane or form approximately the same plane).

FIG. 3C shows a cross-sectional view of an example electronic device 20′. Electronic device 20′ shown in FIG. 3C can be similar to electronic device 20 shown in FIGS. 3A and 3B with the omission of shield 130. In electronic device 20′, the upper and lateral sides of encapsulant 120 can be exposed.

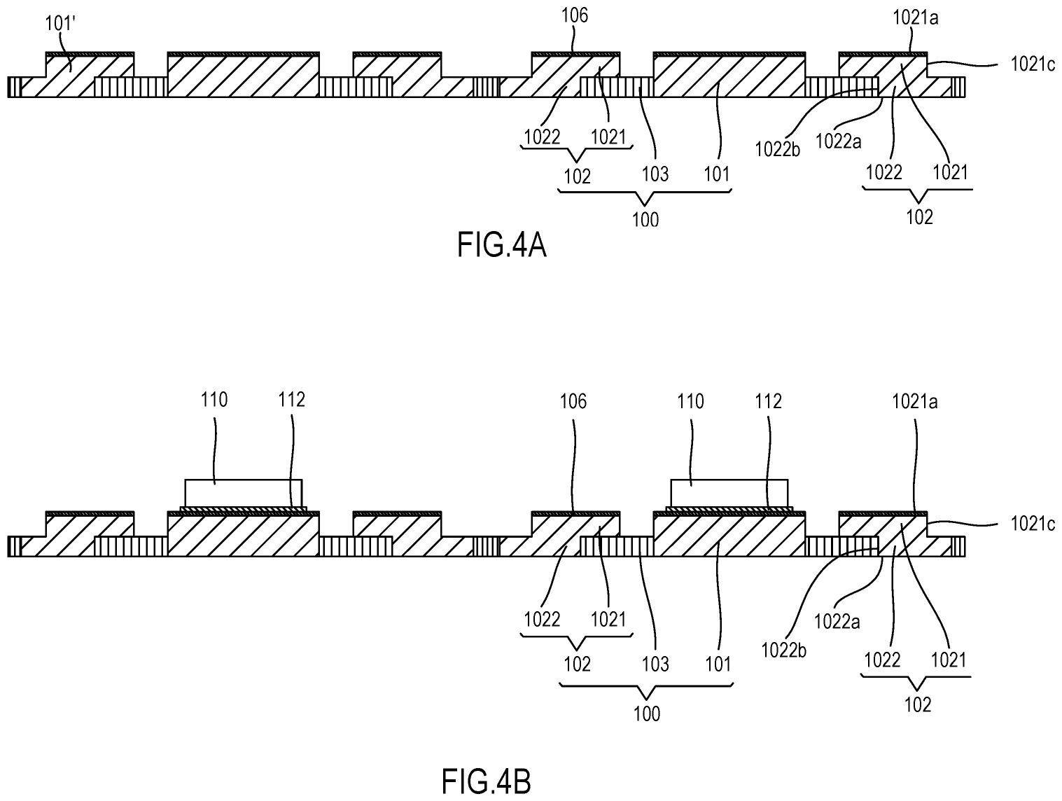

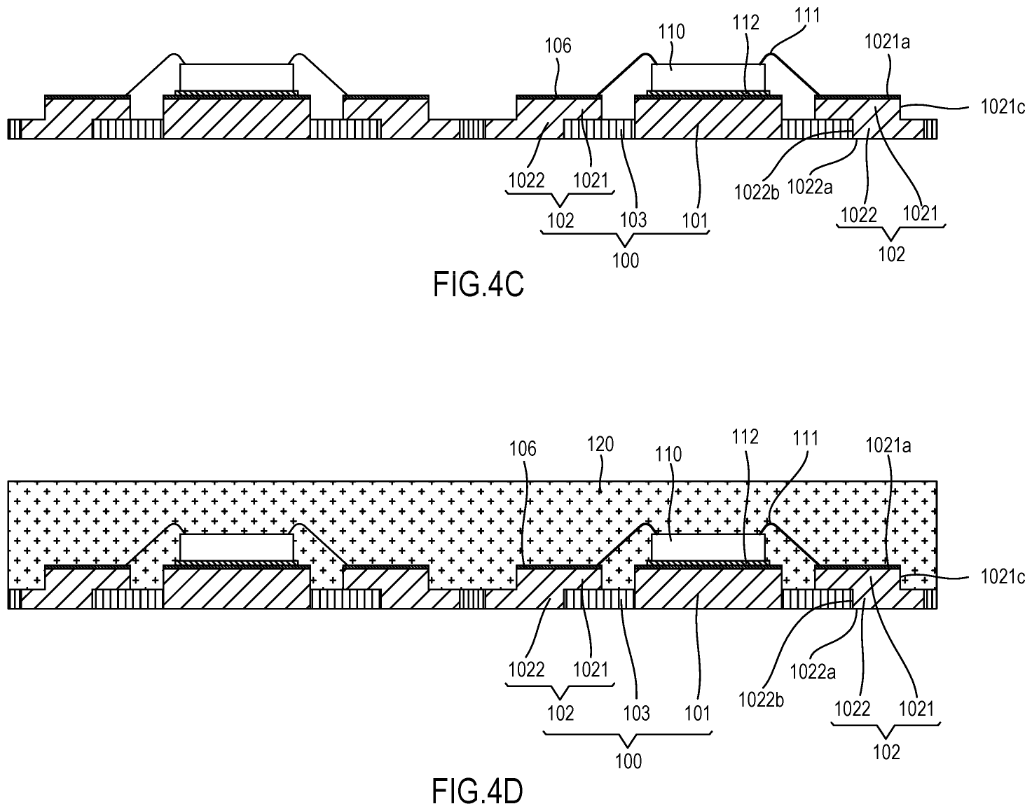

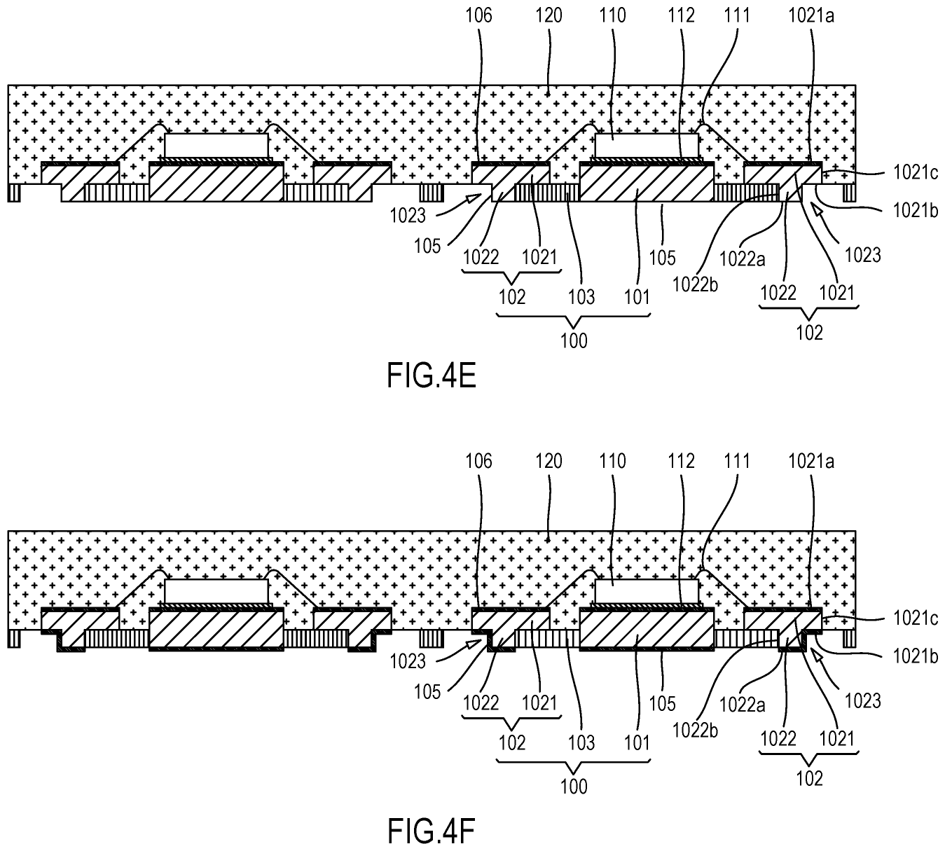

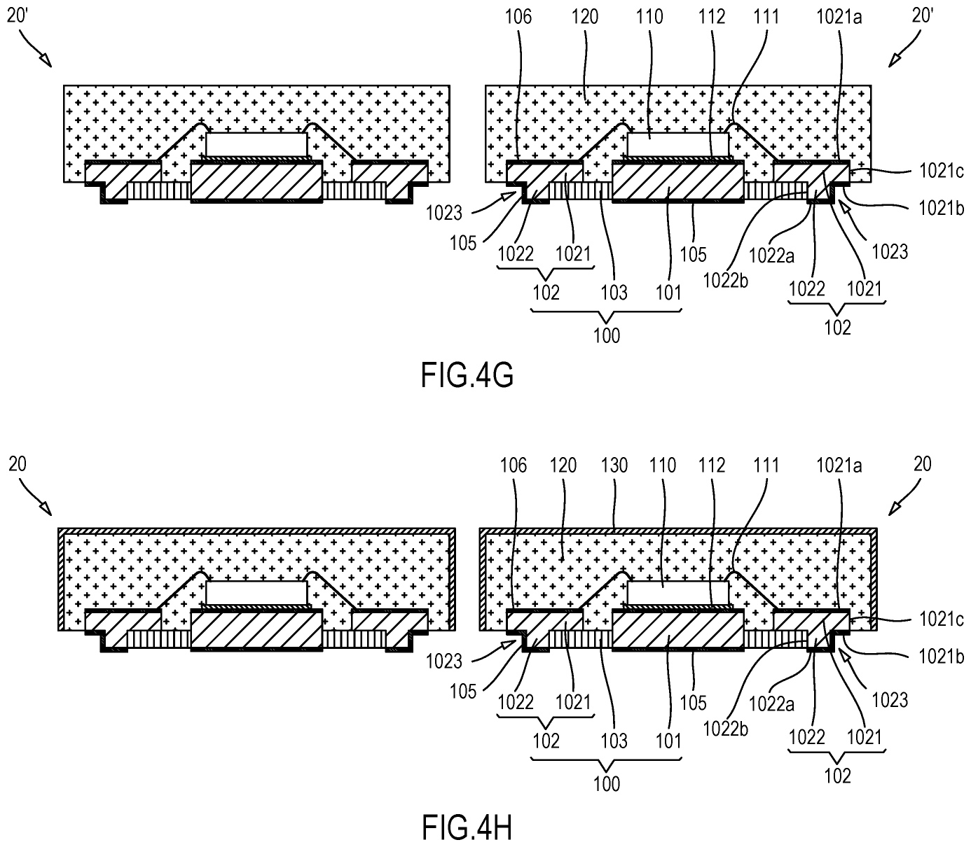

FIGS. 4A to 4H show cross-sectional views of an example method for manufacturing an example electronic device 20 or 20′. In some examples, the process shown in FIGS. 4A to 4H can be referred to as a “wettable flank last” or “die first” process. The process for manufacturing electronic device 20 or 20′ can also include the processes shown in FIGS. 2A to 2D, for example, the process for providing raw material 100′, the process for etching the lower side of raw material 100′, the process for providing lower mold 103, and the process for etching the upper side of raw material 100′.

FIG. 4A shows a cross-sectional view of electronic device 20 or 20′ at a stage of manufacture with lower and upper etching and lower molding having been performed (e.g., after the steps depicted in FIGS. 2A to 2D). In the example shown in FIG. 4A, upper surface finish 106 is provided on die paddle 101 and leads 102. For example, upper surface finish 106 can be provided on base upper side 1021a of leads 102. The materials and process for providing upper surface finish 106 can be similar to or the same as the process described above with reference to FIG. 2G.

FIG. 4B shows a cross-sectional view of electronic device 20 or 20′ at a later stage of manufacture. In the example shown in FIG. 4B, electronic component 110 is coupled to die paddle 101. In some examples, electronic component 110 can coupled to die paddle 101 via attach material 112, as previously described.

FIG. 4C shows a cross-sectional view of electronic device 20 or 20′ at a later stage of manufacture. In the example shown in FIG. 4C, component interconnects 111 are provided. Component interconnects 111 electrically couple electronic component 110 to leads 102. In some examples, component interconnects 111 can electrically couple electronic component 110 to die paddle 101 and/or ground lead 1024 (FIG. 3B). Component interconnects 111 can comprise wires, as previously described.

FIG. 4D shows a cross-sectional view of electronic device 20 or 20′ at a later stage of manufacture. In the example shown in FIG. 4D, encapsulant 120 is provided over electronic component 110 and substrate 100, including die paddle 101, leads 102, and lower mold 103. Encapsulant 120 can cover electronic component 110 and component interconnects 111 and substrate 100. Encapsulant 120 can contact the lateral sides of die paddle 101. Encapsulant 120 can contact base lateral sides 1021c of leads 102. Encapsulant 120 can contact lower mold 103. The materials and process for providing encapsulant 120 can be similar to or the same as the process described above with reference to FIG. 2J.

FIG. 4E shows a cross-sectional view of electronic device 20 or 20′ at a later stage of manufacture. In the example shown in FIG. 4E, wettable flanks 1023 can be provided. In some examples, process for forming wettable flanks 1023 can be similar to or the same as the process described above with reference to FIG. 2F. In response to forming wettable flanks 1023, regions of encapsulant 120 that are adjacent to wettable flanks 1023 can be exposed from the lower side of substrate 100 (e.g., can be exposed through lower mold 103).

FIG. 4F shows a cross-sectional view of electronic device 20 or 20′ at a later stage of manufacture. In the example shown in FIG. 4F, lower surface finish 105 is provided. Lower surface finish 105 can be provided on wettable flanks 1023 of leads 102. In some examples, lower surface finish 105 can be provided on exposed portions of base lower side 1021b and protrusion lateral sides 1022b, and on protrusion lower side 1022a. The materials and process for providing lower surface finish 105 can be similar to or the same as the process described above with reference to FIG. 2G.

FIG. 4G shows a cross-sectional view of electronic device 20 or 20′ at a later stage of manufacture. In the example shown in FIG. 4G, a singulation process is performed to provide individual, discrete electronic devices 20 or 20′. For example, a singulation tool (e.g., a saw, blade, cutter, laser, etc.) can saw or otherwise cut through encapsulant 120 and substrate 100 to separate individual electronic devices 20 or 20′ from one another. a singulation process can be performed. By sawing encapsulant 120 and substrate 100 using a singulation tool, individual electronic devices 20 each including a substrate 100 can be separated from one another. The singulation process can be similar to or the same as the process described above with reference to FIG. 2K.

In response to singulation, the lateral sides of encapsulant 120 and substrate 100 can be coplanar. For example, the lateral sides of encapsulant 120, the lateral sides of lower mold 103 can be coplanar. In response to singulation, the lateral sides of encapsulant 120 and the lateral sides of lower mold 103 are exposed at the outer sides of the device. In this way, electronic device 20′ can be provided.

Singulating through encapsulant 120 and lower mold 103 without sawing through leads 102 can decrease or prevent the generation of metal burrs at the lateral sides of substrate 100. Preventing or decreasing occurrences of burrs and/or having leads 102 covered by encapsulant 120 tends to increase electrical performance and/or reliability, as occurrences of physical bridging (i.e., electrical shorting) between leads 102, which can be caused by metal burrs and/or by environmentally induced Cu migration, is reduced or prevented.

FIG. 4H shows a cross-sectional view of electronic device 20′ at a later stage of manufacture. In the example shown in FIG. 4H, shield 130 can be provided. In some examples, shield 130 can cover the upper and lateral sides of encapsulant 120. The process for providing shield 130 can be similar to or the same as the process described above with reference to FIG. 2L.

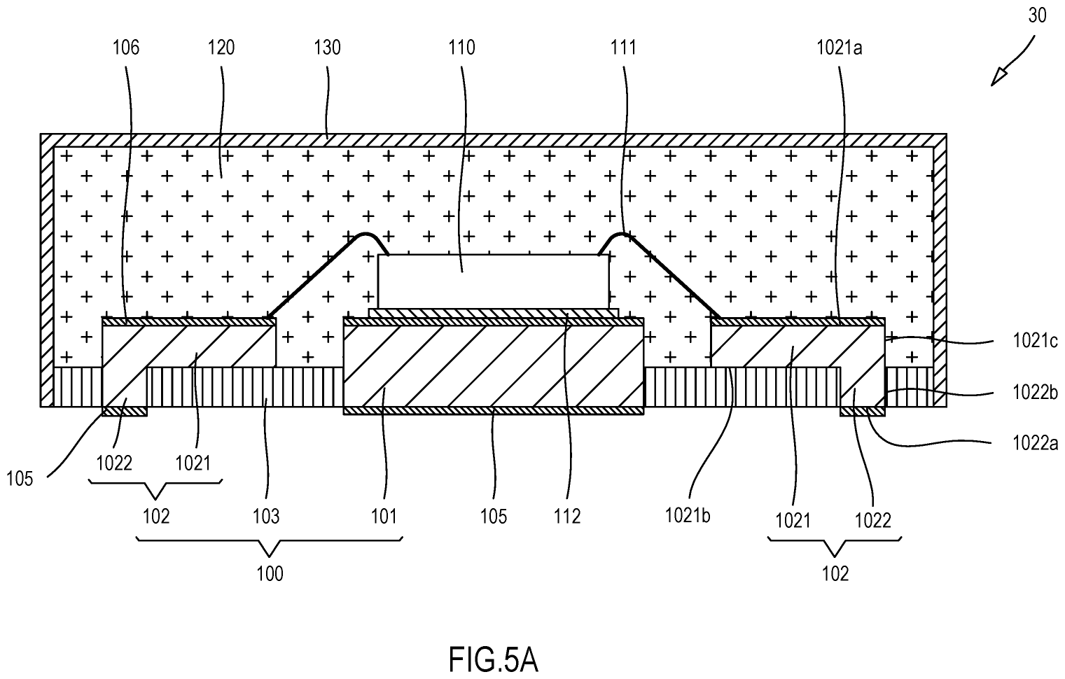

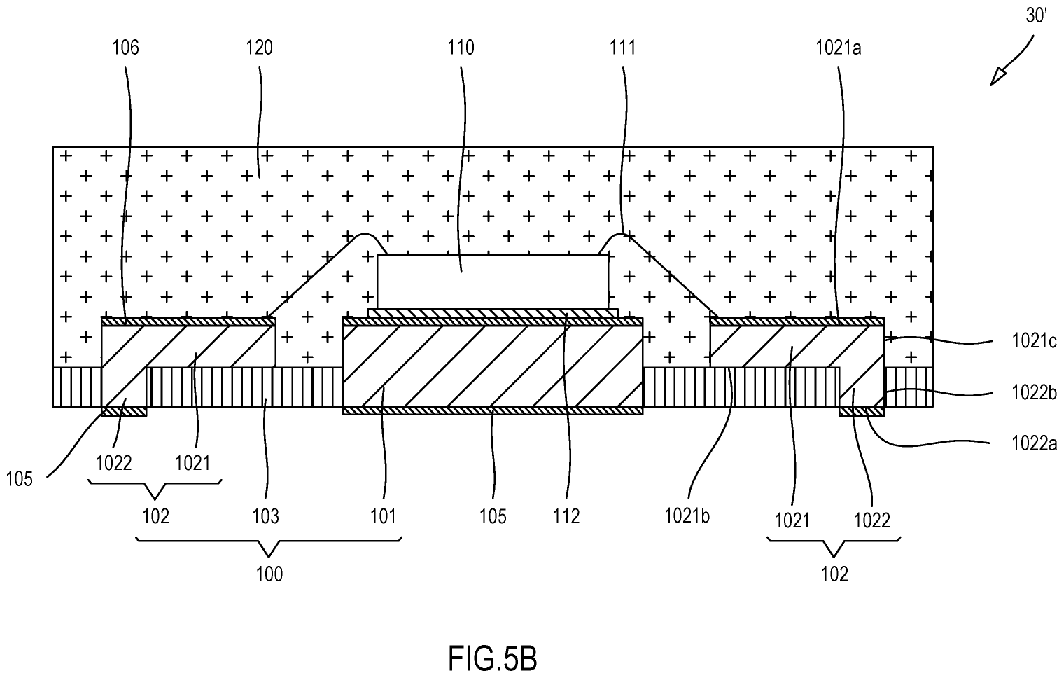

FIG. 5A shows a cross-sectional view of an example electronic device 30. Electronic device 30 shown in FIG. 5A can be similar to electronic device 20 shown in FIGS. 3A and 3B without wettable flanks. In some examples, at least two rows of leads 102 can be arranged in an array or other pattern (e.g., staggered or zig-zag pattern) on a first side (for example, the left side) of die paddle 101. Two or more rows of leads 102 can be arranged in an array or other pattern on a second side (for example, the right side) of die paddle 101 opposite the first side. In some examples, two or more rows of leads 102 can be arranged in an array or other pattern on a third side of die paddle 101 that extends between the first side and second side of die paddle 101, and two or more rows of leads 102 can be arranged in an array or other pattern on a fourth side of die paddle 101 that is opposite the third side and extends between the first side and the second side of die paddle 101. In that regard, lead patterns can surround die paddle 101.

In some examples, leads 102 can comprise or be referred to as isolated pads. Lower mold 103 can be provided between leads 102 and shield 130. Multiple isolated pads can be arrayed in rows and columns about one or more side of die paddle 101. Isolated pads can be formed with narrower pitch, as compared to other leads, which can increase the number of input/output pad and the performance of electronic device 30. Shield 130 enables electronic device 30 to have high design flexibility including the capability of incorporating RF (Radio Frequency) devices. Additionally, due to high design flexibility, the electronic device 30 can comprise a multi-chip module (MCM) or system in package (SiP).

FIG. 5B shows a cross-sectional view of an example electronic device 30′. Electronic device 30′ shown in FIG. 5B can be similar to electronic device 30 shown in FIG. 5A except shield 130 is omitted. In electronic device 30′, the upper and lateral sides of encapsulant 120 and the lateral sides of lower mold 103 can be exposed to ambient conditions in the absence of a shield.

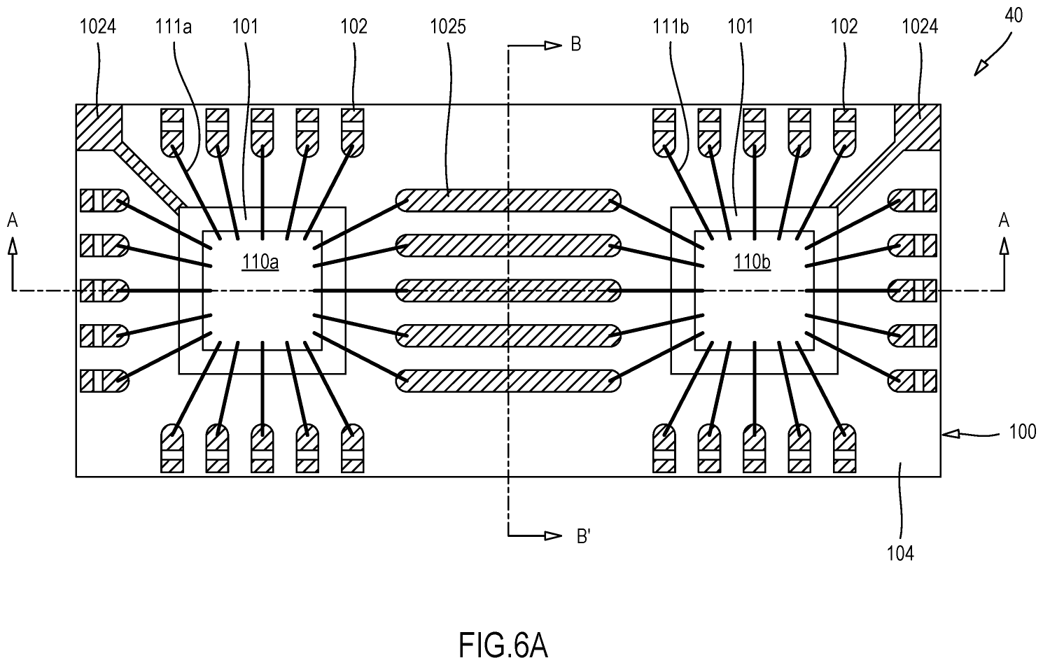

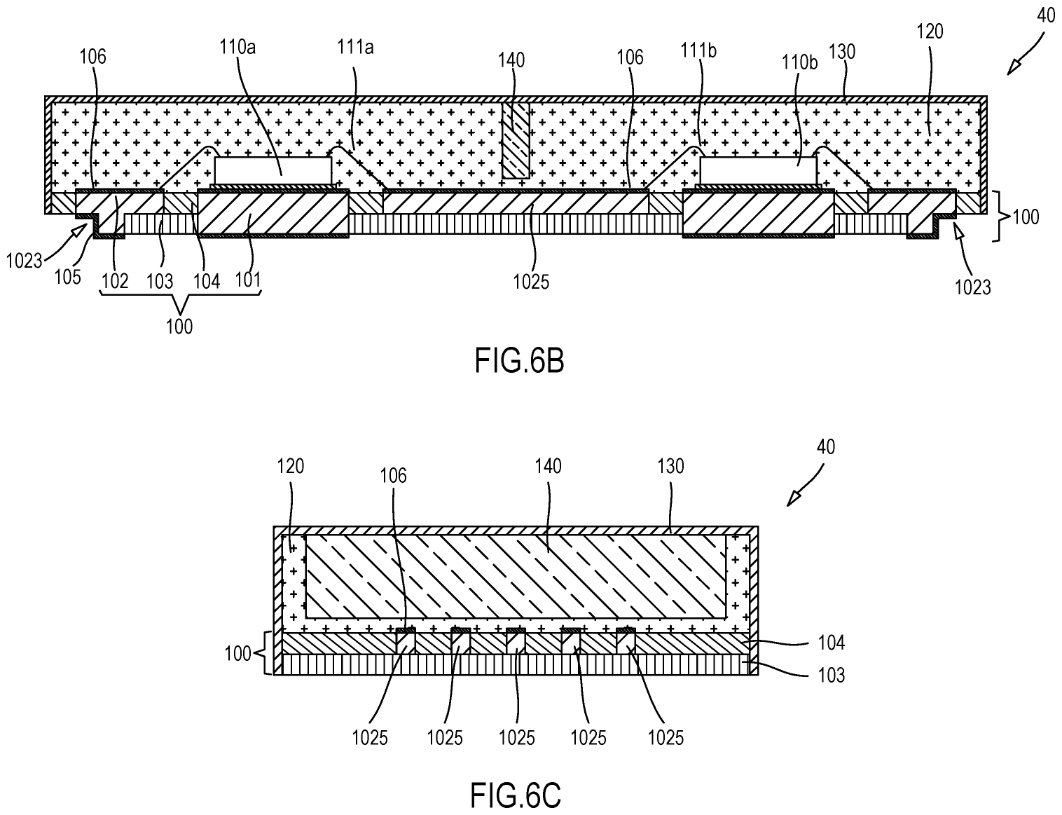

FIG. 6A shows a top perspective view of an example electronic device 40. FIGS. 6B and 6C show a cross-sectional view of electronic device 40. FIG. 6B illustrates a cross-sectional view of electronic device 40 taken along line A-A′ of FIG. 6A. FIG. 6C illustrates a cross-sectional view of electronic device 40 taken along line B-B′ of FIG. 6A.

In various examples, electronic device 40 shown in FIGS. 6A, 6B, and 6C can be similar to electronic device 10 shown in FIGS. 1A, 1B, and 1C, with substrate 100 having bridges 1025. First and second electronic components 110a and 110b can be provided on substrate 100, and a conductor 140 (FIGS. 6B and 6C) can be provided between first electronic component 110a and second electronic component 110b. Conductor 140 can act as an EMI shielding. First electronic component 110a can be electrically connected to leads 102 and bridges 1025 through component interconnects 111a. Second electronic component 110b can be electrically connected to leads 102 and bridges 1025 through component interconnects 111b. Conductor 140 can be electrically connected to and/or can contact shield 130. Conductor 140 can be spaced apart from bridges 1025. For example, encapsulant 120 can be located vertically between conductor 140 and bridges 1025. Conductor 140 can vertically overlap multiple bridges 1025, and bridges 1025 can electrically connect first electronic component 110a and second electronic component 110b.

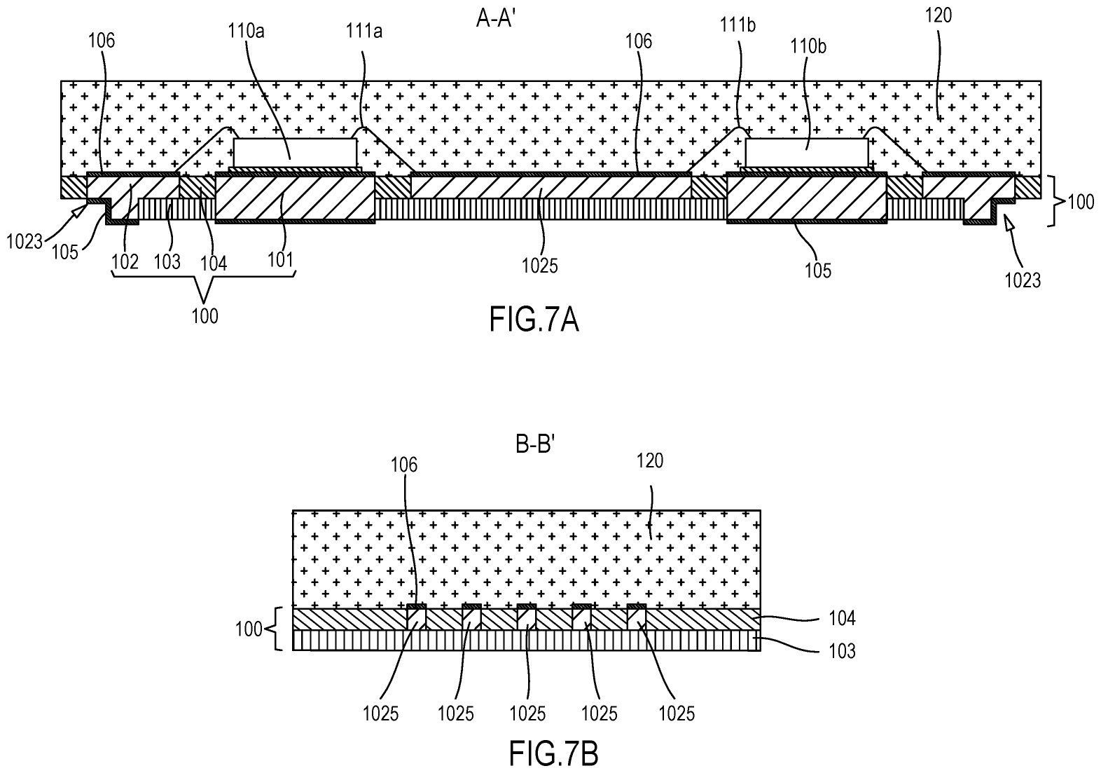

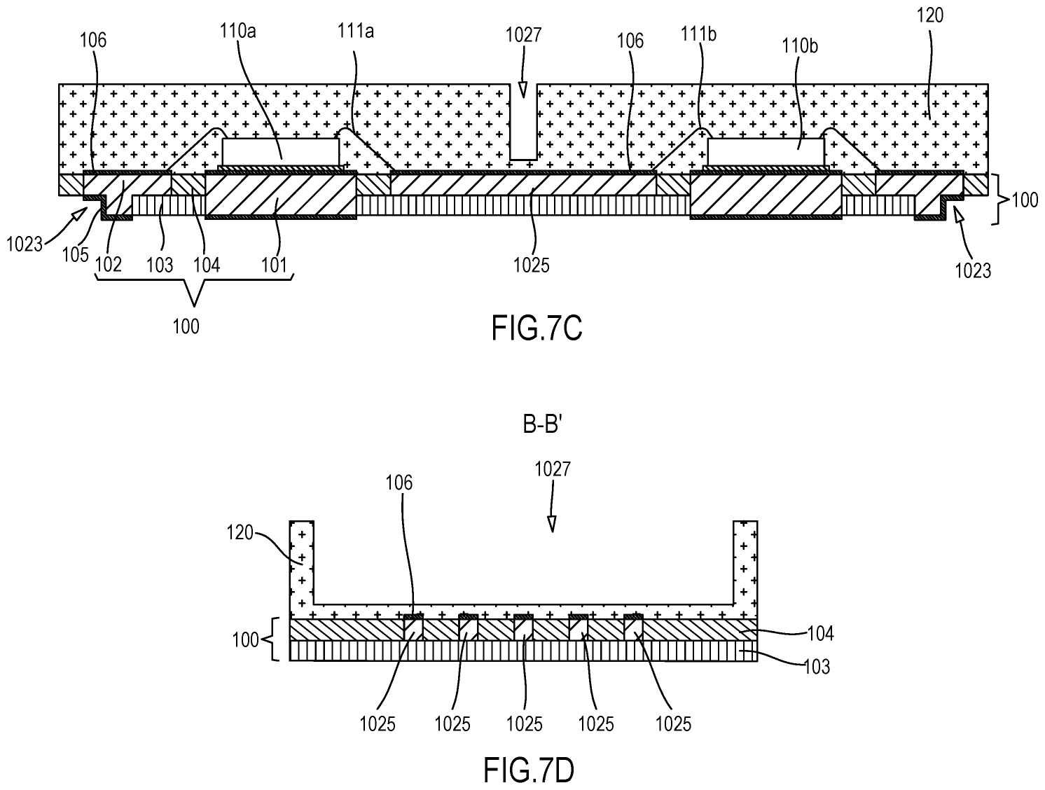

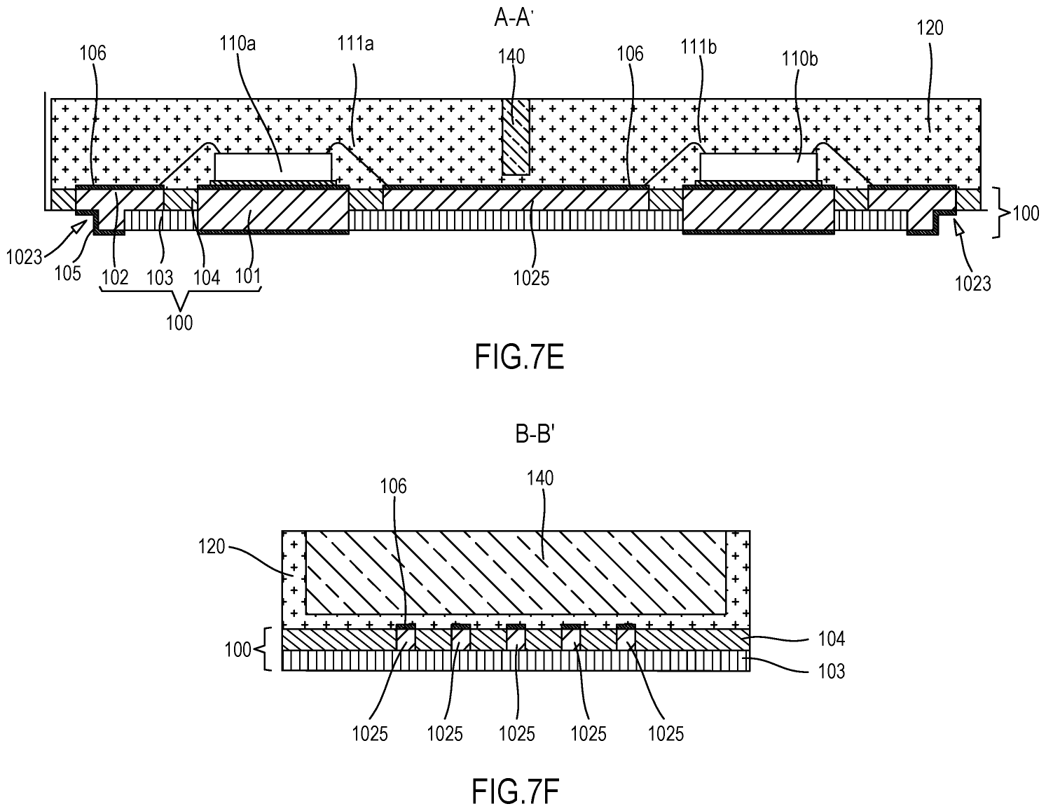

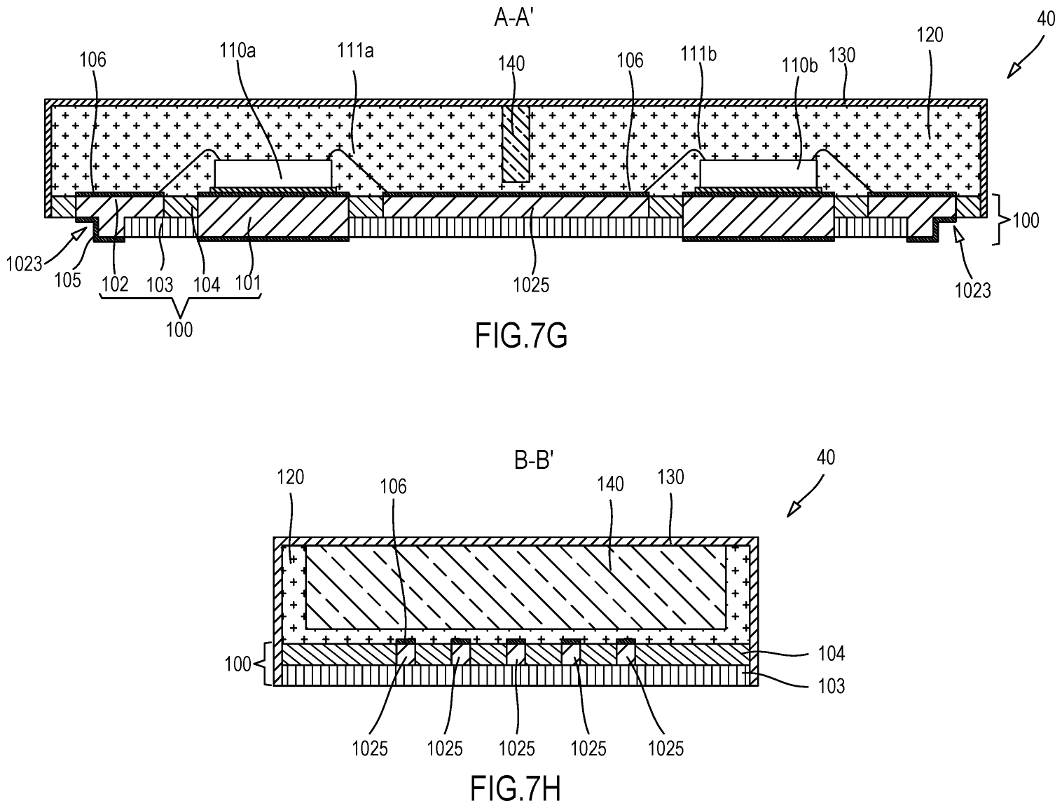

FIGS. 7A to 7H show cross-sectional views of an example method for manufacturing an example electronic device 40. The cross-sectional views shown in FIGS. 7A, 7C, 7E, and 7G correspond to the line A-A′ in FIG. 6A. The cross-sectional views shown in FIGS. 7B, 7D, 7F, and 7H correspond to the line B-B′ in FIG. 6A

FIGS. 7A and 7B show cross-sectional views of electronic device 40 at a later stage of manufacture. For example, electronic device 40, as shown in FIGS. 7A and 7B, can be provided by a manufacturing process similar to the manufacturing process shown in FIGS. 2A to 2J. In some examples, electronic device 40 can be provided using the manufacturing process shown in FIGS. 4A-4F. Electronic device 40 shown in FIGS. 7A and 7B comprises first electronic component 110a and second electronic component 110b disposed over respective die paddles 101. First electronic component 110a can be laterally spaced from second electronic component 110b. Substrate 100 can comprise one or more bridge(s) 1025. In some examples, bridges 1025 can be made of a material similar to leads 102 and die paddle 101. The lateral sides of bridge(s) 1025 can be in and/or can contact upper mold 104. The lower side of bridge(s) 1025 can be located on and/or can contact lower mold 103. The upper side of bridge(s) 1025 and the upper side of upper mold 104 can contact encapsulant 120. The thicknesses of bridge(s) 1025 can range from approximately 50 μm to approximately 100 μm. The lateral width of bridge(s) 1025 can range from approximately 100 μm to approximately 1500 μm. Bridge(s) 1025 can electrically couple first electronic component 110a and second electronic component 110b.

FIGS. 7C and 7D show cross-sectional views of electronic device 40 at a later stage of manufacture. In the example shown in FIGS. 7C and 7D, trench 1027 is provided in encapsulant 120. Trench 1027 can be formed partially through encapsulant 120, such that the depth of trench 1027 is less than the thickness of encapsulant 120. For example, encapsulant 120 can define a floor of trench 1027. In some examples, trench 1027 can vertically overlap multiple bridges 1025. Trench 1027 can comprise or be referred to as a groove, recess, or channel defined by encapsulant 120. Trench 1027 can be provided by a mechanical process, chemical etching, laser ablation, or any other suitable formation process. In some examples, trench 1027 can be provided during deposition of encapsulant 120 (e.g., using a mold chase or other tool that prevents encapsulant from being deposited in the region of trench 1027). The depth of trench 1027 can range from approximately 20 μm to approximately 980 μm. The width of trench 1027 can range from approximately 20 μm to approximately 1480 μm. The bottom side (i.e., floor) of trench 1027 can be spaced apart from bridge(s) 1025 and the upper side of upper mold 104. A separation distance from the bottom side of trench 1027 to the upper side of bridge 1025 and the upper side of upper mold 104 can range from approximately 20 μm to approximately 980 μm. A separation distance between the inner sidewall of trench 1027 (i.e., the inner lateral side of encapsulant 120) and the outer lateral sides of encapsulant 120 can range from approximately 20 μm to approximately 1480 μm. The separation distances can be substantially the same as the thickness of encapsulant 120 at the boundaries defining trench 1027.

FIGS. 7E and 7F show cross-sectional views of electronic device 40 at a later stage of manufacture. In the example shown in FIGS. 7E and 7F, conductor 1025 is provided in trench 1027 (FIGS. 7C and 7D). In some examples, conductor 1025 can fill trench 1027. The upper side of conductor 1025 can be coplanar with the upper side of encapsulant 120. The upper side of conductor 1025 can be exposed through encapsulant 120.

Conductor 1025 can comprise or be referred to as a shield, inner shield, compartment shield, wall, or divider. Conductor 1025 can be made of a metal, or metal alloy. In some examples, conductor 1025 can be a conductive paste. Conductor 1025 can comprise copper (Cu), aluminum (Al), nickel (Ni), palladium (Pd), gold (Au), silver (Ag), chromium (Cr), zinc (Zn), tin (Sn), titanium (Ti), SUS (Fe), carbon black, or alloys thereof. In some examples, a liquid conductive material can fill the trench and heat or light can cure the conductive material to form or provide conductor 1025. Conductor 1025 can be provided in trench 1027 by sputtering, plating, spray coating, diffusion, plasma deposition, or any other suitably deposition method. The thickness and width of conductor 1025 can be similar to the depth and width of the trench.

FIGS. 7G and 7H show cross-sectional views of electronic device 40 at a later stage of manufacture. In the example shown in FIGS. 7G and 7H, shield 130 is provided over encapsulant 120 and conductor 1025. The process for forming shield 130 shown in FIGS. 7G and 7H can be similar to the process for forming shield 130 shown in FIG. 2L or FIG. 4H. Shield 130 can be coupled to conductor 1025. In addition to shielding first and second electronic components 110a, 110b from outside electrical interference, conductor 1025 and shield 130 can inhibit electromagnetic wave interference between first electronic component 110a and second electronic component 110b.

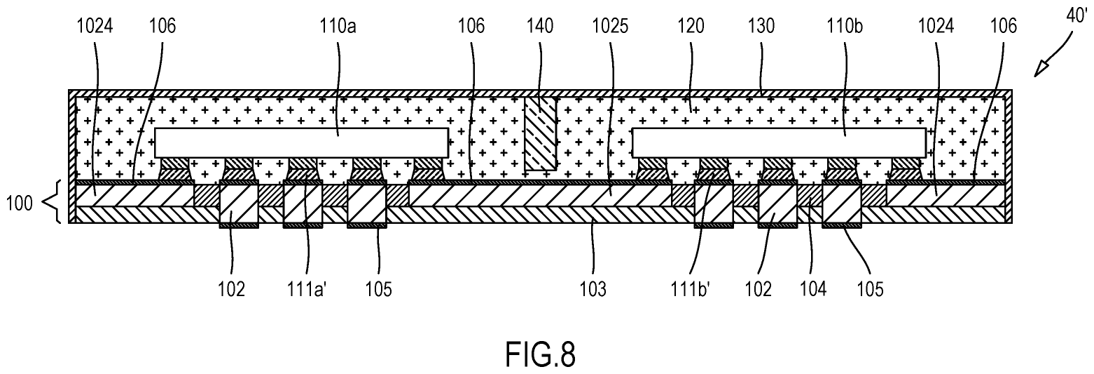

FIG. 8 shows a cross-sectional view of an example electronic device 40′. Electronic device 40′ shown in FIG. 8 can be similar to electronic device 40 shown in FIGS. 6A, 6B, and 6C except electronic components 110a and 110b are electrically connected to substrate 100 using a flip chip method. In some examples, electronic components 110a and 110b can be connected to leads 102 through component interconnects 111a′ and 111b′. Component interconnects 111a′ and 111b can comprise bumps, pillars, solder capped pillars, etc. In some examples, leads 102 can replace die paddle 101 (FIG. 7B). In some examples, one of more of the leads 102 of device 40′ in FIG. 8 can comprise isolated pad arrays, similar to leads 102 of device 30′ in FIG. 5B.

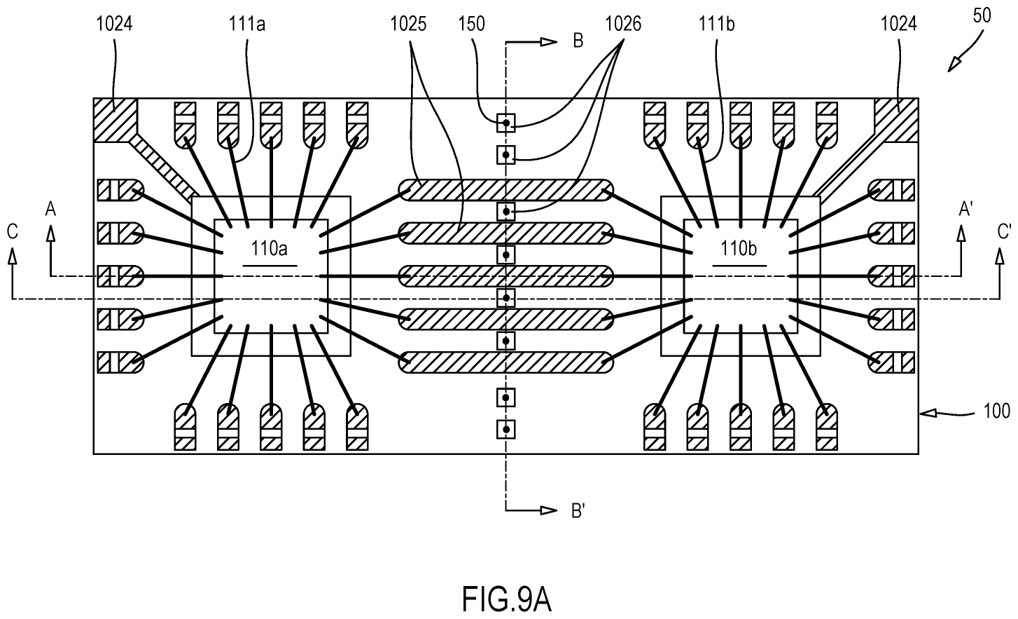

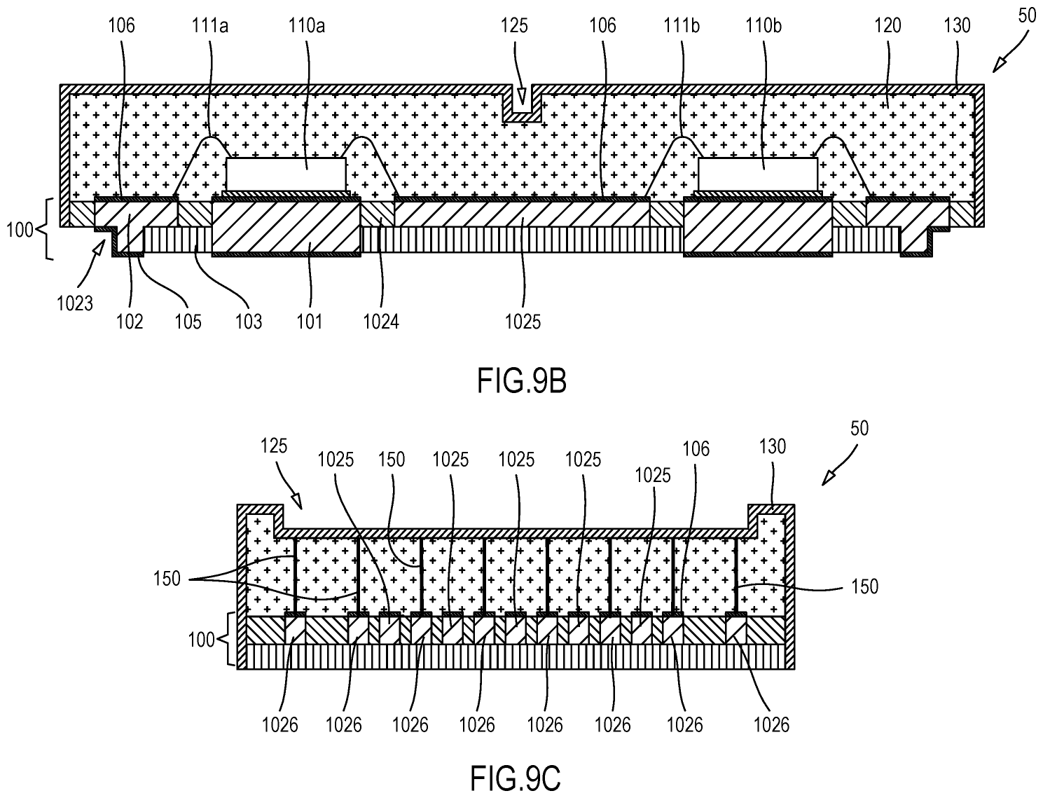

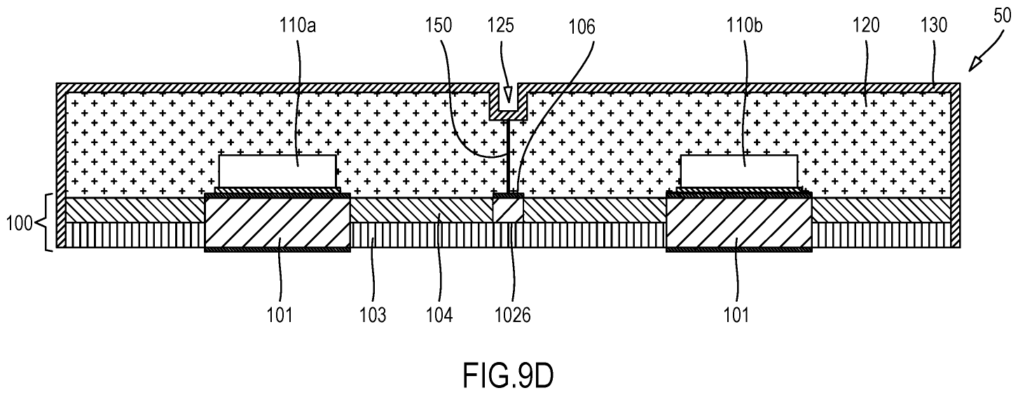

FIG. 9A shows a top perspective view of an example electronic device 50. FIGS. 9B, 9C, and 9D show cross-sectional views of electronic device 50. FIG. 9B is a cross-sectional view taken along line A-A′ of FIG. 9A. FIG. 9C is a cross-sectional view taken along line B-B′ of FIG. 9A. FIG. 9D is a cross-sectional view taken along line C-C′ of FIG. 9A. In accordance with various examples, electronic device 50 can be similar to electronic device 40 shown in FIGS. 6A-6C, with electronic device 50 further comprising conductor supports 1026, conductors 150, and groove 125. Conductors 150 can serve as an EMI shielding and can be coupled to and/or contact shield 130. While electronic device 50 is illustrated with first and second electronic components 110a and 110b coupled to substrate 100 via component interconnects 111a and 111b comprising wires, it is contemplated and understood that in some examples first electronic component 110a and/or second electronic component 110b can be coupled to substrate 100 in a flip chip style, similar to electronic device 40′ in FIG. 8.

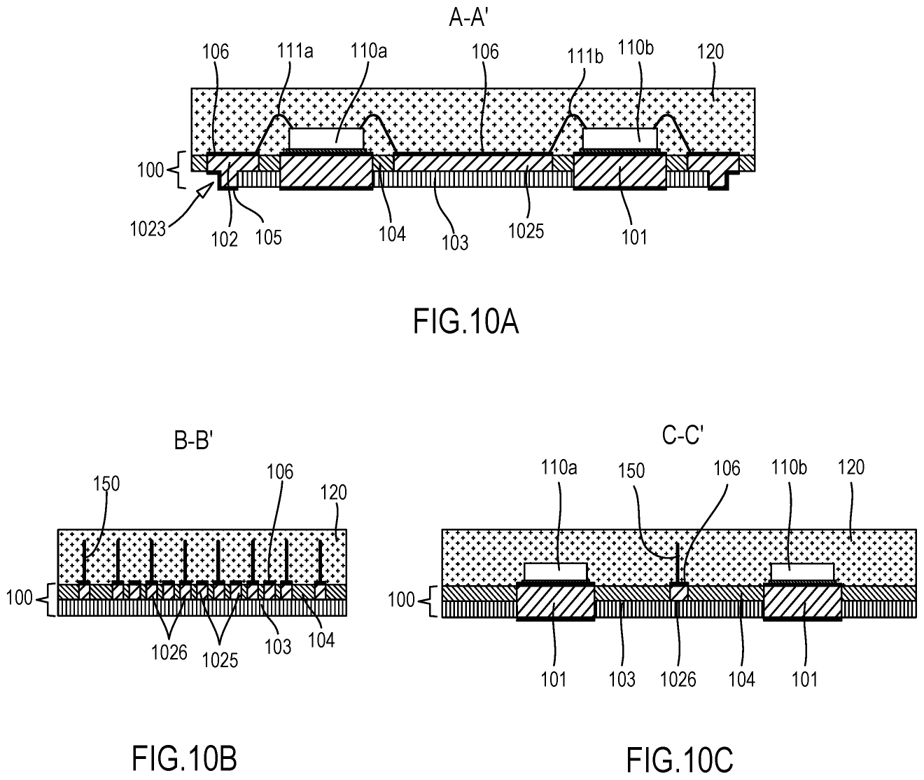

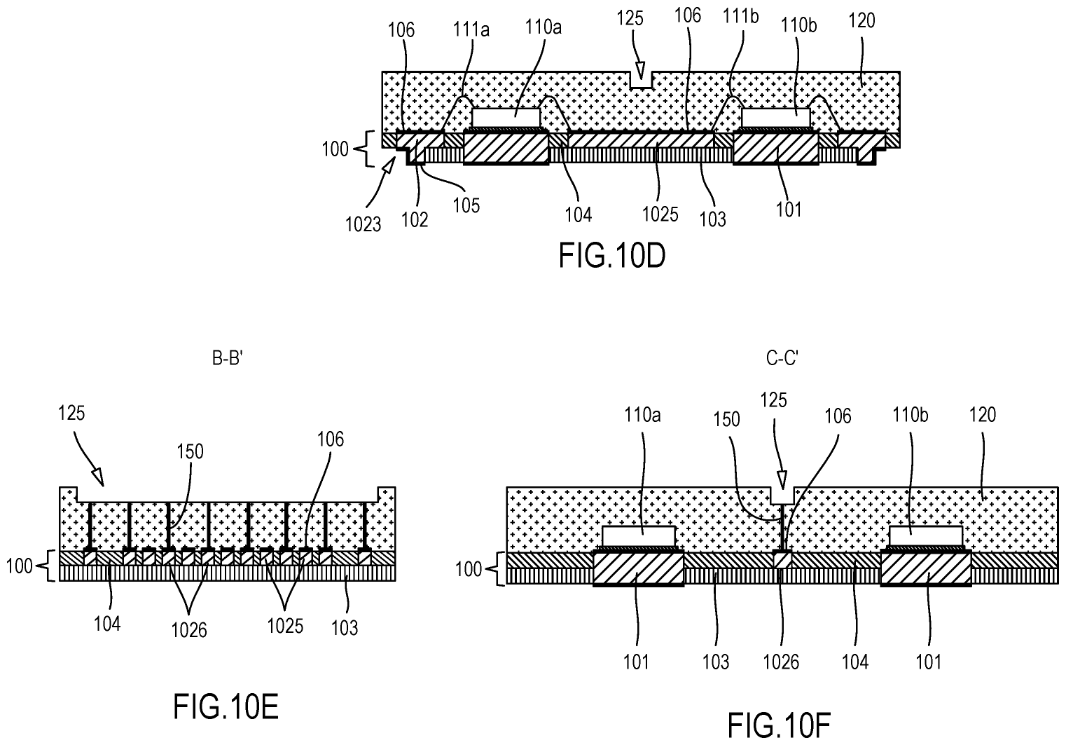

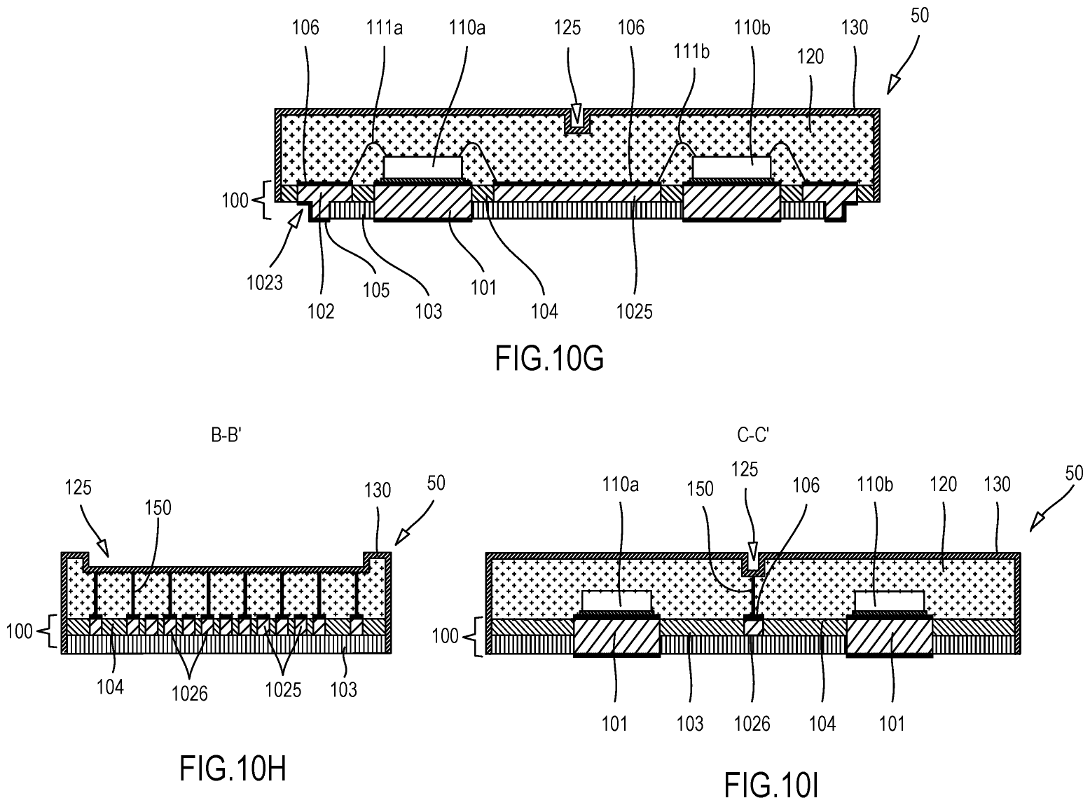

FIGS. 10A to 101 show cross-sectional views of an example method for manufacturing example electronic device 50. The cross-sectional views shown in FIGS. 10A, 10D, and 10G correspond to the line A-A′ in FIG. 9A. The cross-sectional views shown in FIGS. 10B, 10E, and 10H correspond to the line B-B′ in FIG. 9A. The cross-sectional views shown in FIGS. 10C, 10G, and 10I correspond to the line C-C′ in FIG. 9A.

FIGS. 10A, 10B, and 10C show electronic device 50 at a later stage of manufacture. For example, electronic device 50, as shown in FIGS. 10A, 10B, and 10C, can be provided by a manufacturing process similar to the manufacturing process shown in FIGS. 2A to 2J. In some examples, electronic device 50 can be provided using the manufacturing process shown in FIGS. 4A-4F. Substrate 100 of electronic device 500 can include conductor supports 1026. Conductors 150 can be coupled to conductor supports 1026.

Conductor supports 1026 and conductors 150 can be provided laterally between first electronic component 110a and second electronic component 110b. In some examples, conductor supports 1026 and conductors 150 can be mid-way between (i.e., approximately equal distance from) first electronic component 110a and second electronic component 110b. In some examples, conductor supports 1026 and conductors 150 can be closer to first electronic component 110a, as compared to second electronic component 110b. In some examples, conductor supports 1026 can be interleaved between bridges 1025. The lower side of conductor supports 1026 can contact lower mold 103, and the lateral sides of conductor supports 1026 can contact upper mold 104. The upper side of conductor supports 1026 can be coplanar with the upper side of upper mold 104. The upper side of conductor supports 1026 can contact the lower side of encapsulant 120. The material of conductor supports 1026 can be similar to or the same as the material of die paddle 101 and leads 102. The thickness of conductor support 1026 can be similar to the thickness of bridge(s) 1025 and base portion 1021 of leads 102.

Conductors 150 can be provided on conductor supports 1026. Conductors 150 can extend upward from conductor supports 1026. In some examples, the material and diameter of conductors 150 can be similar to the material and diameter of component interconnects 111. In some examples, conductors 150 can comprise or be referred to as conductive wires, metal posts, stacked bumps, or copper columns. In some examples, conductors 150 can extend upward in a straight line on conductor supports 1026. In some examples, the lower ends of conductive wires can be ball-bonded to conductive supports 1026, and the upper ends of conductive wires can be spaced apart from the upper side of encapsulant 120. The lengths of conductors 150 can range from approximately 100 μm to approximately 1500 μm.

FIGS. 10D, 10E, and 10F show cross-sectional views of electronic device 50 at a later stage of manufacture. In the example shown in FIGS. 10D, 10E, and 10F groove 125 is provided in encapsulant 120. Groove 125 vertically overlaps conductors 150. In some examples, groove 125 can be provided to span multiple bridges 1025 and multiple conductor supports 1026 and conductor 150. Groove 125 can be formed to a depth suitable to expose the upper ends of conductors 150. The depth of groove 125 can range from approximately 20 μm to approximately 980 μm. The process for forming groove 125 can be similar to or the same as the process for forming trench 1027, as described above with reference to FIGS. 7C and 7D.

FIGS. 10G, 10H, and 10I show cross-sectional views of electronic device 50 at a later stage of manufacture. In the example shown in FIGS. 10G, 10H, and 10I, shield 130 can be provided. Shield 130 can be provided over the top and lateral sides of encapsulant 120. Shield 130 can be provided in groove 125 (FIGS. 10D, 10E, and 10F). The process for forming shield 130 shown in FIGS. 10G, 10H, and 10I can be similar to the process for forming shield 130 in FIGS. 2L, 4H, or 7C and 7D. Shield 130 can be coupled to conductors 150. For example, shield 130 can be coupled to and/or can contact the top ends of conductors 150 that are exposed along floor of groove 125. Conductors 150 and shield 130 tend to shield electromagnetic waves to inhibit EMI. In addition to shielding first and second electronic components 110a, 110b from outside electrical interference, conductors 150 and shield 130 can inhibit electromagnetic wave interference between first electronic component 110a and second electronic component 110b.

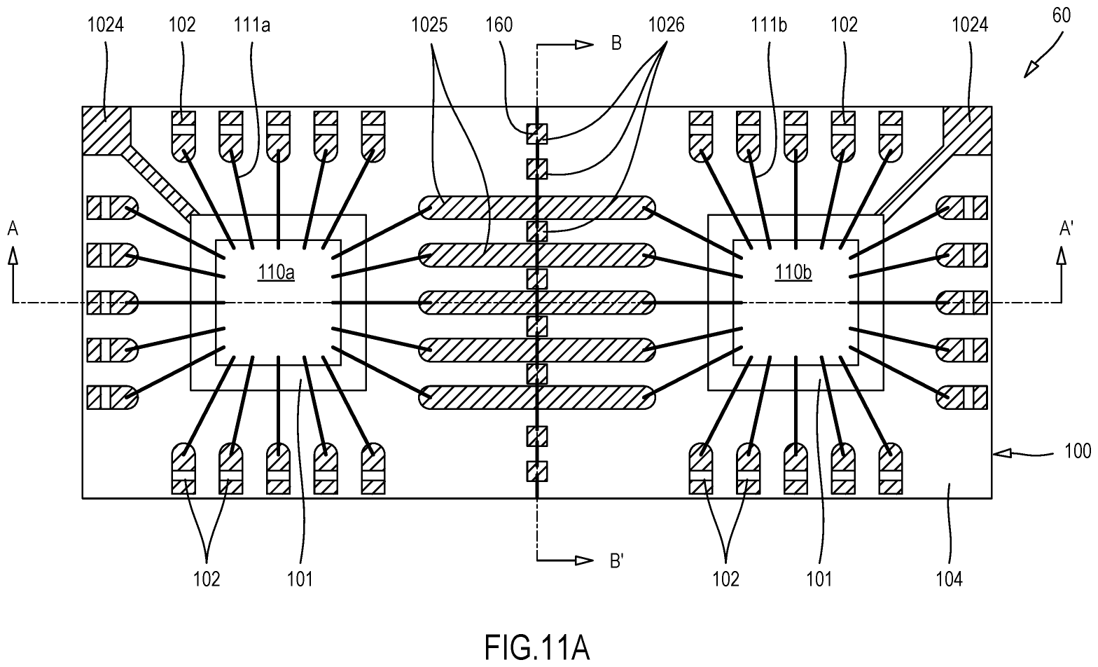

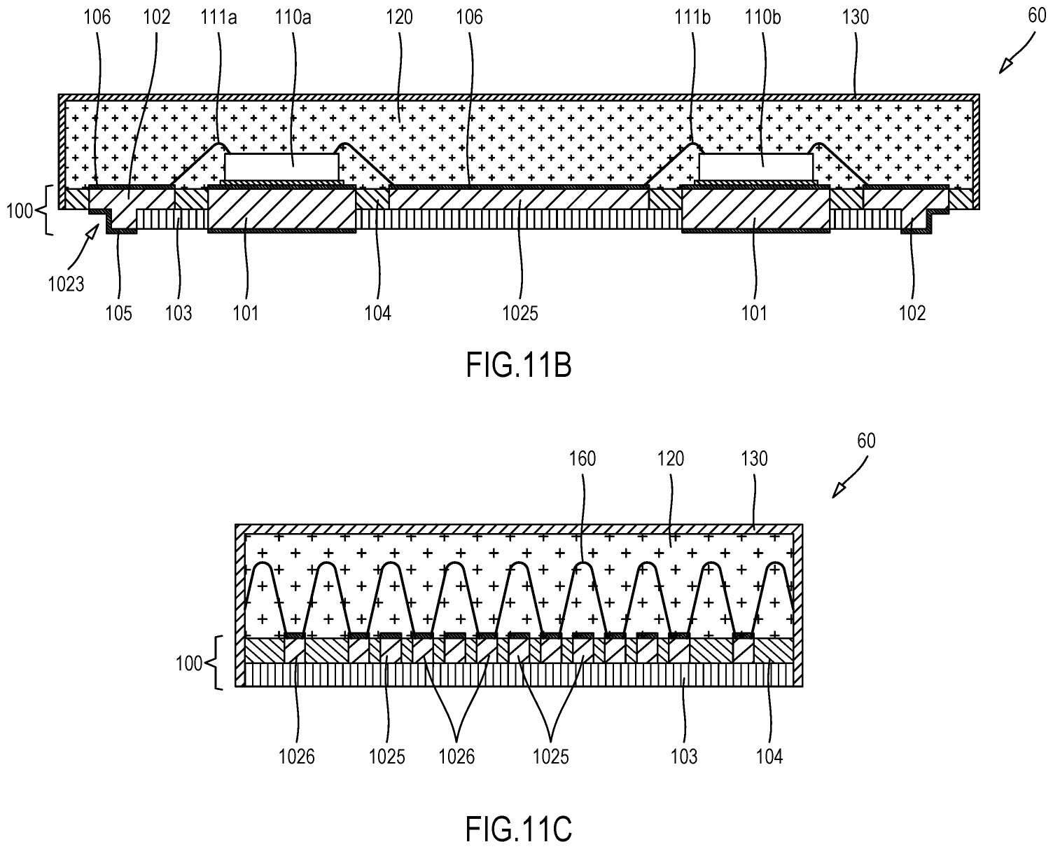

FIG. 11A shows a top perspective view of an example electronic device 60. FIGS. 11B and 11C show cross-sectional views of example electronic device 60. FIG. 11B illustrates a cross-sectional view taken along line A-A′ of FIG. 11A. FIG. 11C illustrates a cross-sectional view taken along line B-B′ of FIG. 11A.

In accordance with various examples, electronic device 60 can be similar to electronic device 50 shown in FIGS. 9A to 9D, with one or more conductor(s) 160 extending between conductor supports 1026. While electronic device 60 is illustrated with first and second electronic components 110a and 110b coupled to substrate 100 via component interconnects 111a and 111b comprising wires, it is contemplated and understood that in some examples first electronic component 110a and/or second electronic component 110b can be coupled to substrate 100 in a flip chip style, similar to electronic device 40′ in FIG. 8.

In some examples, conductors 160 be provided in a curved shape, an angled shape, a bent shape, an upside down “U” shape, or upside down “V” shape. In some examples, one end or portion of conductor 160 can be bonded to a first conductor support 1026, and the opposite end or portion of the conductor 160 can be bonded to a second conductor support 1026. In some examples, conductor 160 can traverse bridge 1025. For example, conductor 160 can extend over or vertically overlap bridge 1025. In some examples, conductor 160 can comprise or be referred to as a wire fence, conductive wire, or wire loop. Conductor supports 1026 can be electrically coupled or shorted by multiple conductors 160. In some examples, conductor 160 can comprise one, unitary or integral piece that extends between and is bonded to multiple conductor supports 1026. In other examples, conductors 160 can be multiple discrete structures with each conductor extending between, for example, two conductor supports 160 and with two conductors 160 coupled to the same conductor support.

In some examples, the end of one or more conductor(s) 160 can be located at an outer edge or perimeter of encapsulant 120 and can be coupled to and/or contact shield 130. For example, an end of the conductor 160 can be exposed from encapsulant 120. In some examples, one or more conductor support(s) 1026 can extend to an outer edge or perimeter of encapsulant 120 and can be coupled to and/or contact shield 130. In some examples, conductors 160, conductor supports 1026, and shield 130 can all be electrically coupled. Electronic device 60 can also be referred to as a “wire fence” type electronic device. Conductor(s) 160 and shield 130 tend to shield electromagnetic waves to inhibit EMI. In addition to shielding first and second electronic components 110a, 110b from outside electrical interference, conductor(s) 160 and shield 130 can inhibit electromagnetic wave interference between first electronic component 110a and second electronic component 110b.

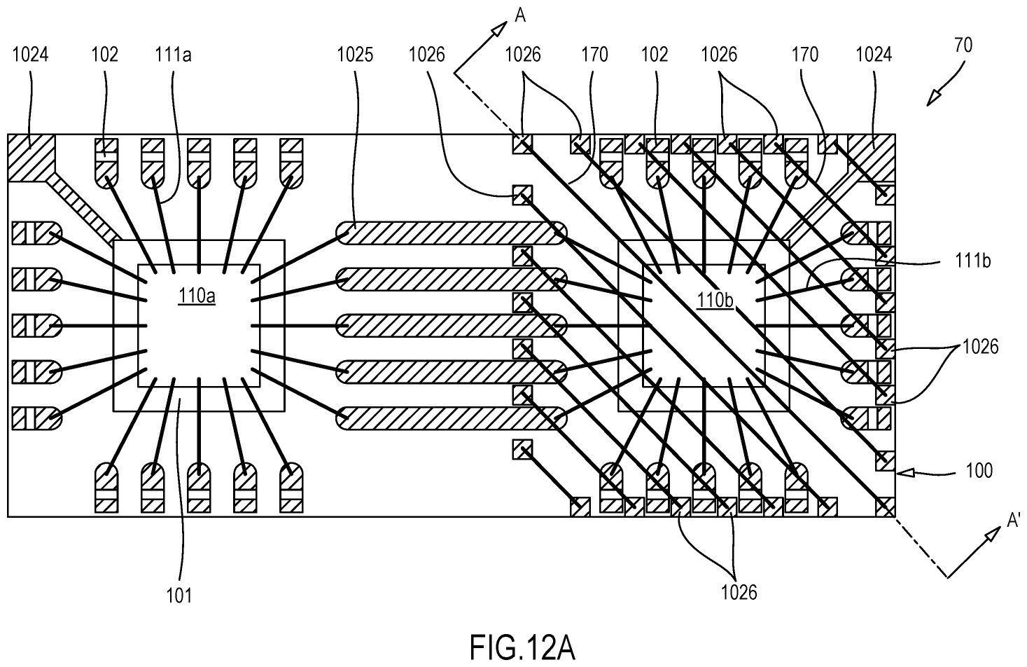

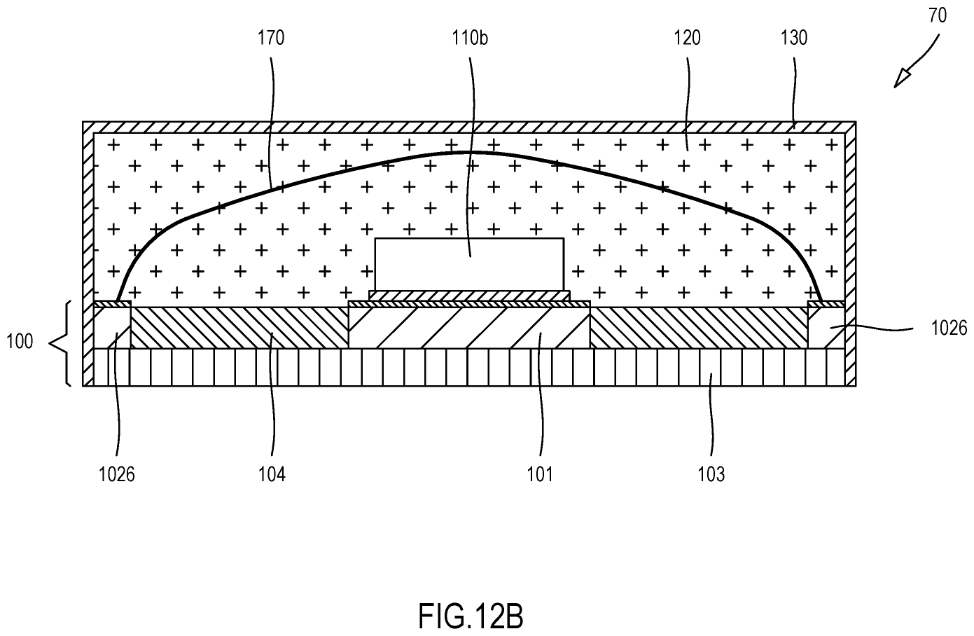

FIG. 12A shows a top perspective view of an example electronic device 70. FIG. 12B shows a cross-sectional view of electronic device 70 taken along line A-A′ of FIG. 12A. In the example shown in FIGS. 12A and 12B, electronic device 70 can be similar to electronic device 60 shown in FIGS. 11A and 11B, with conductors 170 extending over and vertically overlapping second electronic component 110b. While electronic device 70 is illustrated with first and second electronic components 110a and 110b coupled to substrate 100 via component interconnects 111a and 111b comprising wires, it is contemplated and understood that in some examples first electronic component 110a and/or second electronic component 110b can be coupled to substrate 100 in a flip chip style, similar to electronic device 40′ in FIG. 8.

In accordance with various examples, conductor supports 1026 can be provided between bridges 1025 and also between leads 102. Conductor supports 1026 can be arranged generally around second electronic component 110b. Conductor supports 1026 can be spaced apart from second electronic component 110b and surround second electronic component 110b. Conductor supports 1026 can be arranged in a substantially square or rectangular perimeter around second electronic component 110b. The lateral sides of some of the conductor supports 1026 can be coplanar with the lateral sides of encapsulant 120 and/or with the lateral sides of upper mold 104. The lateral sides one or more conductor supports 1026 can be coupled to and/or contact shield 130.

Conductors 170 can be connected to conductor supports 1026 in a curved shape, an angled shape, a bent shape, an upside down “U” shape, or an upside down “V” shape. In some examples, conductors 170 can comprise or be referred to as a wire cage, conductive wire, or wire loop. Conductors 170 can generally surround the upper and lateral sides of second electronic component 110b. Conductors 170 can be connected to two conductor supports 1026, for example, a first conductor support 1026 located at first side of second electronic component 110b and a second conductor support 1026 located at second side of second electronic component 110b. Conductors 170 can be connected to opposing conductor supports 1026 along or in parallel with the line virtually connecting opposite corners. The lengths of conductors 170 can be different. The lengths of conductors 170 close to the center of die paddle 101 or second electronic component 110b can be relatively long, and the length of conductor 170 farthest from die paddle 101 or second electronic component 110b can be relatively short. In some examples, conductors 170 can be provided in a direction crossing or generally perpendicular to ground lead 1024. In some examples, conductors 170 can be provided in a direction generally parallel to ground lead 1024. The heights of conductors 170 can be greater than the heights of component interconnects 111. Conductors 170 can be spaced apart from component interconnects 111. The material and diameter of conductors 170 can be similar to the material and diameter of component interconnects 111. In some examples, electronic device 70 can also be referred to as a “wire cage” type electronic device. Conductors 170 and shield 130 tend to shield electromagnetic waves to inhibit EMI. In addition to shielding first and second electronic components 110a, 110b from outside electrical interference, conductors 170 and shield 130 can inhibit electromagnetic wave interference between first electronic component 110a and second electronic component 110b.

Electronic devices of the present disclosure can provide wettable flanks without Cu exposure. The upper molding and lower molding techniques tend to result in improved device reliability and avoid introduction of metallic burrs into electronic devices. Various EMI shielding techniques can be integrated with wettable flanks for high design flexibility in RF devices and other devices. Isolated pads in an rtMLF can generate high-performance devices with high input/output counts.

The present disclosure includes reference to certain examples, however, it will be understood by those skilled in the art that various changes may be made and equivalents may be substituted without departing from the scope of the disclosure. In addition, modifications may be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
leads comprising a conductive material, wherein a lead from the leads includes a base portion and a protrusion extending from a lower side of the base portion;
a die paddle between the leads and comprising the conductive material;
a lower mold on a first lateral side of the protrusion and around lateral sides of the die paddle;
a lower surface finish applied to a lower side of the protrusion; and
an electronic component coupled to the die paddle and in electronic communication with the lead.

2. The electronic device of claim 1, further comprising an upper mold disposed over the lower mold and around lateral sides of the base portion and the die paddle.

3. The electronic device of claim 2, wherein the lead is separated from the die paddle by the upper mold and the lower mold.

4. The electronic device of claim 1, further comprising an encapsulant disposed over the electronic component, over the lower mold, and around lateral sides of the base portion and the lateral sides of the die paddle.

5. The electronic device of claim 1, wherein the lower surface finish is applied to a lower side of the base portion, to a second lateral side of the protrusion opposite the first lateral side of the protrusion, and to the lower side of the protrusion to form a wettable flank.

6. The electronic device of claim 1, further comprising a shield disposed over the electronic component and around lateral sides of the base portion of the lead.

7. The electronic device of claim 6, further comprising a ground lead formed integrally with the die paddle and electrically coupled to the shield.

8. The electronic device of claim 6, further comprising:
a second electronic component lateral to the first electronic component;
a bridge comprising the conductive material, wherein the die paddle is between the lead and the bridge; and
an electromagnetic interference (EMI) shielding disposed over the bridge and between the first electronic component and the second electronic component, wherein the EMI shielding is electrically coupled to the shield.

9. The electronic device of claim 8, wherein the EMI shielding comprises a wire fence, a conductive paste, or a vertical wire.

10. The electronic device of claim 6, further comprising a wire cage extending around the lateral sides of the electronic component and electrically connected to the shield.

11. The electronic device of claim 1, wherein the lead is enclosed by the lower surface finish, the lower mold, an upper mold disposed around lateral sides of the base portion, and an upper surface finish applied to an upper side of the lead.

12. The electronic device of claim 1, wherein the lower surface finish comprises a silver-plating layer.

13. The electronic device of claim 1, wherein the lower mold is on a second lateral side of the protrusion opposite the first lateral side.

14. A method of manufacturing an electronic device, comprising:
providing leads comprising a conductive material, wherein a lead from the leads includes a base portion and a protrusion extending from a lower side of the base portion;
providing a die paddle comprising the conductive material and disposed between the leads;
providing a lower mold on a first lateral side of the protrusion and around lateral sides of the die paddle;
applying a lower surface finish to a lower side of the protrusion; and
providing an electronic component coupled to the die paddle and in electronic communication with the lead.

15. The method of claim 14, further comprising providing an upper mold over the lower mold and around lateral sides of the base portion and the die paddle.

16. The method of claim 14, further comprising providing an encapsulant over the electronic component, over the lower mold, and around lateral sides of the base portion and the lateral sides of the die paddle.

17. The method of claim 14, wherein the lower surface finish is applied to a lower side of the base portion, a second lateral side of the protrusion opposite the first lateral side of the protrusion, and the lower side of the protrusion to form a wettable flank.

18. The method of claim 14, wherein the lead is separated from the die paddle by an upper mold and the lower mold.

19. The method of claim 14, wherein the lead is enclosed by the lower surface finish, the lower mold, an upper mold disposed around lateral sides of the base portion, and an upper surface finish applied to an upper side of the lead.

20. An electronic device, comprising:
a lead comprising a conductive material and including a base portion and a protrusion extending from a lower side of the base portion;
a die paddle adjacent the lead and comprising the conductive material;
a lower mold on a first lateral side of the protrusion and around lateral sides of the die paddle, wherein the lower mold is between the lead and the die paddle;
a surface finish applied to a lower side of the protrusion to form a wettable flank; and
an electronic component coupled to the die paddle and in electronic communication with the lead.
